(19) United States
(12) Patent Application Publication
(10) Pub. No.: US 2023/0376642 A1
(43) Pub. Date: Nov. 23, 2023

(54) Luminaire Designs Selection Method

(71) Applicant: Schreder S.A., Bruxelles (BE)

(72) Inventors: Maxime Dietens, Liège (BE); Paul Bawin, Liège (BE); Vincent Lang, Liège (BE); Roxane Caprara, Liège (BE); Benoît Kerff, Liège (BE)

(21) Appl. No.: 18/044,143

(22) PCT Filed: Sep. 8, 2021
(86) PCT No.: PCT/EP2021/074723

§ 371 Date: Mar. 6, 2023

(30) Foreign Application Priority Data
Sep. 8, 2020 (NL) 2026431

(51) Int. Cl. G06F 30/13

(52) U.S. Cl. CPC G06F 30/13

(57) ABSTRACT

A method for selecting and sorting at least one luminaire design, said method comprising the following steps performed by a computer means: obtaining a first and a second luminaire installation characteristic associated to a first and a second lighting site, respectively, wherein each of the first and the second lighting site corresponds to a location for installing at least one luminaire neighboring a pathway; selecting, based on the first luminaire installation characteristic, on the second luminaire installation characteristic, on a database with a plurality of luminaire designs, a list comprising for each lighting site at least one suitable luminaire design with at least one suitable configuration parameter of said plurality of luminaire designs, wherein a luminaire design may be the same or different for the first and the second lighting site; sorting the list based on at least one preferential parameter.

### FIELD OF INVENTION

The field of invention relates to luminaire designs selection methods and computer-controlled methods. Particular embodiments relate to a luminaire design selection method, and a computer-controlled method, in order to obtain a selection of at least one suitable luminaire design for a plurality of lighting sites.

### BACKGROUND

Methods to compose luminaire designs are readily available and typically comprise the filling out of an extensive list of parameters, optical and geometrical parameters for example, in order to determine the best suited theoretical luminaire design for a given lighting site. The list of parameters is usually provided manually by a user of a computer-implemented method. These parameters reflect the optical considerations and the installation possibilities of the lighting site. The user can then tinker with some parameters to obtain a luminaire design actually corresponding to an existing product. Other parameters can be considered to account for constraints from different origins: optimization, regulation, monetary, product availability, etc. Obtaining such luminaire design is a time-consuming operation and the computer-implemented method is typically not user-friendly for the non-initiated user. Also, depending on the user, some information relevant for the luminaire design and/or the lighting site may be easily overlooked.

Further, when dealing with an installation project having multiple lighting sites, the user generally has to repeat the same steps for each of the lighting sites as if they are independent one from the other. However, doing so may not be in the best interests of the installation project. There is thus a need for a method able to take into account these additional interests.

### SUMMARY

The object of embodiments of the invention is to provide a luminaire design selection method and a computer-controlled method thereof, allowing for a more complete and optimized integration of parameters related to a plurality of lighting sites, for example in the case of large tenders. According to an aspect of the invention, there is provided a method for selecting and sorting at least one luminaire design. The method comprises the following steps preferably performed by a computer means, preferably performed in the order specified:
obtaining a first luminaire installation characteristic associated to a first lighting site;
obtaining a second luminaire installation characteristic associated to a second lighting site;
wherein each of the first lighting site and the second lighting site corresponds to a location for installing at least one luminaire neighboring a pathway;
optionally, associating a first weight to the first lighting site and a second weight to the second lighting site, said first weight and second weight being related to a comparison between the first lighting site and the second lighting site;
selecting, based on the first luminaire installation characteristic, on the second luminaire installation characteristic, on a database with a plurality of luminaire designs, and, optionally, based on parameters of a lighting regulation, and/or, optionally, based on the first weight of the first lighting site and on the second weight of the second lighting site, a list comprising for each lighting site at least one suitable luminaire design with at least one suitable configuration parameter of said plurality of luminaire designs, wherein a luminaire design may be the same or different for the first lighting site and the second lighting site;
sorting the list based on a preferential parameter, preferably based on or related to a compatibility level with the first lighting site and the second lighting site, and, optionally, based on the first weight of the first lighting site and on the second weight of the second lighting site.
   By taking into account, in a single selection step, installation characteristics associated to a first and a second lighting site, the selection step may be optimized. The sorting step of the selected list will allow having a view of the best luminaire designs which follow a given preferential parameter, thereby satisfying the main interest for a project englobing the first and the second lighting sites.

The lighting site may be defined following different categories, each category corresponding to a different illumination scheme and/or type of a pathway within and/or neighboring the related lighting site. The lighting site may correspond to any one of: a standard motorway section, a pedestrian crossing, a pedestrian zone, a square, a bicycle lane, a standard street section, a crossroad, a conflict zone, a marketplace, a bridge, an industry hall, an airport, a stadium, a warehouse, etc. Generally, types of pathways are defined according to lighting regulations, or standards, of the geographical area where the lighting site is located, such as EN13201, IES RP-8, CIE 115.

The luminaire installation characteristic may correspond to optical characteristics of the environment of the lighting site to be illuminated, and/or to dimensions relevant for the installation of a luminaire. The plurality of luminaire designs in the database comprising the plurality of luminaire designs may each be associated to one or more configuration parameters from which the suitability to the optical characteristics of the lighting site to be illuminated and/or to the dimensions of the lighting site relevant for the installation of a luminaire may be deducted. By an elimination process, a list of at least one suitable luminaire design for each lighting site can be selected.

By suitability, it is meant the ability for the luminaire design to satisfy some lighting regulations, e.g. a public road lighting standard or recommendations such as EN 13201, IES RP-8, CIE 115, respective to the environment of the lighting site, thereby allowing for an illumination giving a visibility above a predetermined level for users of the lighting site, as well as giving a predetermined illumination safety, e.g. illumination intensity below a blinding intensity, light emitted within a certain arc to avoid glaring angles. The suitability of the luminaire design arises from the inclusion in the luminaire design of at least one suitable configuration parameter. The at least one suitable configuration parameter may correspond to a physical parameter of the luminaire design, i.e. mechanical parameters, e.g. luminaire head fixation method, luminaire head housing, luminaire compartments accesses, luminaire family, and/or optical parameters, e.g. average illuminance of a luminaire head, lighting distribution of the luminaire head, glaring index of the luminaire head, transversal uniformity of the emitted light, longitudinal uniformity of the emitted light, photometric accessories, and/or electrical parameters, e.g. power consumption, type of electrical connections, mains connections, type of driver, lamp/led type and wattage, lighting lifetime, and/or installation parameters, e.g. spacing, height, secondary functional unit.

Additionally, a compatibility level of the luminaire design respective to its corresponding lighting site may be defined. The compatibility level refers not only to the suitability, i.e. whether it is suitable or not to illuminate the lighting site, but is also a measure of how much the configuration parameters of the luminaire design are suited to the at least one installation characteristic of the lighting site in order to obtain desired illumination and working conditions of the luminaire design. For example, a luminaire design could be suitable for a lighting site in terms of illumination, but would need to be driven at a high power with respect to nominal working conditions in order to do so, thereby decreasing the compatibility level of the luminaire design respective to the lighting site.

To each lighting site may correspond a certain number of luminaires to be installed. These numbers may be used to determine a weight of the corresponding lighting site in the overall installation project. Additionally or alternatively, the weight of the corresponding lighting site may be determined based on an expected electricity consumption of the lighting site relative to the overall expected electricity consumption of all lighting sites. The determined weights may then be optionally used when selecting and/or sorting the list of the at least one luminaire design.

The preferential parameter used for the sorting of the list may be a single parameter attributed by default, a preferential parameter selected by a user, or a plurality of preferential parameters. In an embodiment, in implementing the method, an interface may be provided allowing inputting the one or more preferential parameters.

The obtaining of the luminaire installation characteristic may be similar or different for the first and the second lighting sites. The first luminaire installation characteristic and the second luminaire installation characteristic may be of a similar or different type for the first and the second lighting sites. The luminaire installation characteristic may be obtained via a manual entry from the user, taken from a memory, or obtained through a processing of data. In an embodiment, there may be a first plurality of luminaire installation characteristics associated to the first lighting site and a second plurality of luminaire installation characteristics associated to the second lighting site with one or more common luminaire installation characteristics between the first lighting site and the second lighting site. The obtaining may thus be advantageously implemented to simplify the obtaining of the second plurality of luminaire installation characteristics by simply copying the one or common luminaire installation characteristics, thereby avoiding unintentional mistakes.

Also, optionally, the sorting step of the method may be followed by another step comprising the provision of a report to the user, said report comprising the list of the at least one suitable luminaire design, each of the at least one suitable luminaire design being accompanied by its respective summarized characteristics. The summarized characteristics may comprise: a product image of the luminaire design, configuration parameters of the luminaire design, links to documents related to the luminaire design, managing options of the luminaire design, secondary functional unit options such as possibilities for additional sensors to be installed, commercial information etc.

According to a preferred embodiment, each of the first luminaire installation characteristic and the second luminaire installation characteristic comprises one or more, preferably at least two of, more preferably at least three of: a pathway width, an interval distance between two neighboring luminaire base supports, a pathway surface material, pathway surface optical properties, a height of a luminaire head of the at least one luminaire, a number of lanes of the pathway, one or more circulation directions of the pathway, a lateral distance between the pathway and the at least one luminaire base support, a lateral dimension of a hard shoulder of the pathway, an arrangement pattern of a group of luminaires including the at least one luminaire along the pathway, a bracket length of the luminaire head of the at least one luminaire, an inclination of the luminaire head of the at least one luminaire, a presence of a base support for a luminaire, a location of the base support respective to the one or more circulation directions, a proximity with a neighboring building, characteristics of the neighboring building, a number of luminaire heads per base support, a presence of a conflict zone in the lighting site, a type of the pathway.

In an embodiment, the lighting site may already be provided with luminaires including a base support, e.g. a luminaire pole, a wall fixation, and the required luminaire designs may be for a retrofitting of the lighting site. In another embodiment, the lighting site does not have base supports for luminaires or new base supports may also be reinstalled on the lighting site. The conflict zone may be defined as a zone where there is an increased potential for collision between pathway users, e.g. entry or exit lanes to the motorway, crossroads, roundabouts, pedestrian crossings, etc. The type of the pathway may be defined according to the type of user of the pathway, e.g. pedestrian, bicycle, motorized vehicle, according to the number of lanes and dimensions of the pathway, e.g. a street, a motorway, a secondary road, a local road, a road, a footpath, a sidepath, and/or according to an amount and frequency of traffic. The type of the pathway is usually classified on a national level taking into account one or more of the above mentioned parameters.

The pathway may be a pathway of a lighting site suitable for outdoor luminaires which is used as a path for vehicles and/or pedestrians. By lighting site for outdoor luminaires, it is meant roads, tunnels, industrial plants, stadiums, airports, harbors, rail stations, campuses, parks, cycle paths, pedestrian paths, or pedestrian zones for example, and outdoor luminaires can be used notably for the lighting of an outdoor area, such as roads and residential areas in the public domain, private parking areas and access roads to private building infrastructures, etc. In other embodiments according to the invention, the pathway may be located indoors, such as in a warehouse or an industry hall.

According to an exemplary embodiment, the sorted list includes a first luminaire design suitable for the first lighting site, and a second luminaire design suitable for the second lighting site, said first luminaire design and second luminaire design having at least one similar or identical configuration parameter.

Preferably, the at least one similar or identical configuration parameter comprises at least one of: a luminaire family, a luminaire head housing, a light source unit, an optical unit, a luminaire driver.

In this manner, there may be luminaire designs suitable for at least two lighting sites sharing similarities in their conception, which allows optimizing the overall logistics of the luminaire installation project as well as potentially reducing the number of spare parts to be kept in stock for maintenance.

In an embodiment, there may be two luminaire designs suitable for the first lighting site belonging to different luminaire families, and one luminaire design suitable for the second lighting site of the same luminaire family as one of the luminaire designs associated to the first lighting site.

The sorted list may include the two luminaire designs sharing the same luminaire family. In another embodiment, the sorted list includes the same luminaire design for both the first lighting site and the second lighting site. In preferred embodiments, the total number of different luminaire designs in the sorted list may be less than the number of lighting sites.

By luminaire family, it is meant a group of luminaires derived from a common luminaire platform and being made by similar production processes, or having similar physical characteristics. By light source unit, it is meant the light source of the luminaire head comprising a predetermined number of e.g. LEDs, said LEDs provided to a predetermined support. By optical unit, it is meant optical elements shaping the light emitted from the light source unit, e.g. an array of lens elements, reflectors, backlights, filters, collimators, anti-glare frames.

It is to be noted that the aim of the invention is to produce a list of luminaire designs and increase the similarities between luminaire designs belonging to different lighting sites in order to lighten the load during installation, maintenance and/or logistic operations while still maintaining a considerable level of compatibility of each luminaire design with the corresponding lighting site.

According to a preferred embodiment, the first lighting site and/or the second lighting site comprises at least five luminaires to be installed, preferably at least ten luminaires to be installed.

In this way, the method may be utilized for a relatively sizeable project and its use allows a gain of time in selecting and sorting the list of the at least one luminaire design.

It is to be noted that the lighting site corresponds to a category of lighting site to be illuminated defined according to a type of illumination scheme required and/or according to the type of the pathway within and/or neighboring the related lighting site. So, the lighting site is not restricted to a geographical location and may be divided into several geographical locations. For example, in an embodiment, the first lighting site corresponds to a lighting site neighboring a street and may be divided into five luminaires to be installed in a first street section and two luminaires to be installed in a second street section, and the second lighting site corresponds to a pedestrian crossing with two luminaires to be installed on each side of the pedestrian crossing. According to an exemplary embodiment, the preferential parameter is related to any one of: a compatibility level with a lighting site, a luminaire family, an installation budget, a number of luminaires to be installed, a maximum wattage of the at least one luminaire to be installed, an aesthetical consideration, a type of light source, a glaring index, a luminaire managing option, a number of parts of a luminaire design, a lighting uniformity, a lighting intensity, an average illuminance (on the pathway or on a side of the pathway), a total cost of ownership, a lifetime, a method of installation, an operating temperature, a recycling factor, a certificate such as a technical certificate, a commercial brand, an electrical connection type, a compliancy with a lighting regulation, a power consumption per kilometer, a secondary functionality of the luminaire.

By secondary functionality of the luminaire, it is meant the use of a secondary function unit such as a sensing means, e.g. light sensor, biological hazard sensor, sound sensor, temperature sensor, proximity sensor, image-capturing sensor, and/or the use of antennas, and/or other devices, e.g. sanitizing device, loudspeaker, display, charging device such as vehicle charging device, as additional functionalities of the luminaire design aside from illumination.

By this approach, one can obtain a more comprehensive view of the list according to one's interests.

In an embodiment, the preferential parameter may be the luminaire family, and the list will be sorted by trying to obtain the highest number of lighting sites with luminaire designs of the same luminaire family.

In another embodiment, the preferential parameter may be the power consumption per kilometer, and the list will be sorted by trying to obtain for each lighting site the luminaire design with the lowest power consumption per kilometer. The power consumption per kilometer may be calculated by setting a type of the pathway and a minimum illuminance and processing how much power would be needed to illuminate a given length of said type of the pathway under these conditions.

In yet another embodiment, the preferential parameter may be the number of luminaires designs to be installed, and the list will be sorted by trying to obtain the luminaire design to be installed with the lowest installation density with respect to the lighting site.

In still another embodiment, the preferential parameter may be the luminaire managing option, and the list will be sorted by a type of controller chosen, e.g. Zhaga pluggable controller, NEMA pluggable controller.

In again another embodiment, the preferential parameter may be the number of parts of a luminaire design, and the list will be sorted by trying to obtain for each lighting site the luminaire design with the simplest structure, i.e. with the lowest number of parts.

In a further embodiment, the preferential parameter may be the number of parts used for the at least one luminaire design for each lighting site, and the list will be sorted by trying to obtain the lower number of different parts between each lighting site. In this way, compatibility of the at least one luminaire design between multiple lighting sites may be increased and maintenance can be facilitated by reducing the number of different parts in stock.

It is to be noted that in sorting the list, the user of the method may specify a minimum number of luminaire designs per lighting site, if possible, in the sorted list.

According to a preferred embodiment, the method further comprises:
providing an input corresponding to a third luminaire installation characteristic of the first lighting site and/or the second lighting site; and
wherein the selecting of the list of the at least one suitable luminaire design is further based on the third luminaire installation characteristic.

In this manner, additional luminaire installation characteristics may be provided to complete the first and second luminaire installation characteristics obtained. Luminaire installation characteristics may be provided from various sources. For example the third luminaire installation characteristic may be provided via a manual input by a user using an inputting means, e.g. a keyboard. Alternatively, the third luminaire installation characteristic may originate from a database of known luminaire installation characteristics and/or based from measured data and/or processed data.

According to an exemplary embodiment, the method further comprises:
providing an input corresponding to another preferential parameter relative to the plurality of luminaire designs;
sorting the list of the at least one suitable luminaire design further based on the another preferential parameter.

In this way, a plurality of preferential parameters may be considered to better reflect one's interests. In an embodiment, each of the plurality of preferential parameters may be weighted according to a picking order, said picking order reflecting the order of importance amongst the plurality of preferential parameters. Also, each of the plurality of preferential parameters may be associated with a tolerance level. By tolerance level, it is meant an indication of how much a value of the preferential parameter may be modified for a given selected luminaire design to end in the sorted list. Additionally or alternatively, an interface may be outputted to allow a user to select the preferential parameter and/or the another preferential parameter.

According to a preferred embodiment, the method further comprises:
obtaining, from a regulation database, a regulation e.g. a lighting regulation associated to the first lighting site and/or the second lighting site; and
wherein the selecting of the list of the at least one suitable luminaire design is further based on the obtained lighting regulation.

In this manner, the selected list may be funneled further to be better suited to the location of the first lighting site and/or the second lighting site by taking into account another kind of parameter. This improves the modularity of the method in obtaining suitable luminaire designs for the first and second lighting sites. The lighting regulation may correspond to a legal obligation or recommendation based on the kind of the identified pathway, the amount of traffic, the type of users of the pathway, etc. The regulation database may be a nation-wide database, a region-wide database, a city-wide database, or a local-wide database. In an embodiment, the obtaining of the lighting regulation may be based on the geo-coordinates of the lighting site or part of the lighting site. Additionally or alternatively, the obtaining of the lighting regulation may be at least partially based on the obtained luminaire installation characteristics, e.g. the number of lanes of the pathway. In an embodiment, the obtaining of the lighting regulation may be followed by a manual correction or confirmation of the lighting regulation associated to the lighting site. Also, the obtaining of the lighting regulation may be achieved by a manual entry via an input interface.

According to an exemplary embodiment, the method further comprises:
obtaining, from a stock database, a list of available luminaire parts; and
wherein the selecting of the list of the at least one suitable luminaire design is further based on the obtained list of available luminaire parts.

In this way, the selected list of the at least one suitable luminaire design reflects an actual product availability. Indeed the luminaire design may comprise a certain number of luminaire parts, e.g. a luminaire driver, a lighting unit, an optical unit, ESD, SPD, fuses, a luminaire head housing, sensing means, to be gathered with various parts being essential or interchangeable. The availability of parts may change the overall characteristics of a luminaire design. The stock database may be luminaire parts available in a stock of a local provider, in a stock of a luminaire producer, in a catalogue of products, or in a personal stock. The availability may be further distinguished between available in stocks, discontinued, in production, and/or with a time indication of the availability on the lighting site for installation. The list of available luminaire parts may also comprise a quantity of available luminaire parts, an end-of-life date of available luminaire parts, a manufacturing country of the luminaire parts, an ecological label of the luminaire parts. Such way of refining the selected list of the at least one suitable luminaire design provides for a more informed choice of a luminaire design based on a reality of the readily available items. In an embodiment, the selecting of the list of the at least one suitable luminaire design may be based on luminaire designs favoring available luminaire parts whose quantity in stocks is high, which are subject to a special price offer, and/or which are close to the end-of-life date.

Also, in an embodiment, the sorting of the list may be followed by the provision of a purchase selection interface. The purchase selection interface may allow the user, after selection of at least one desired luminaire design from the sorted list of the at least one suitable luminaire design, to conclude by ordering the at least one desired luminaire design for installing to the corresponding lighting site.

According to a preferred embodiment, the selecting of the list of the at least one suitable luminaire design is further based on a further luminaire installation characteristic of a further lighting site.
In this manner, a relative uniformity between lighting sites may be attained. The first and second luminaire installation characteristics and the further luminaire installation characteristic may be of similar or different kinds. In one embodiment, the further lighting site does not need to have luminaires being installed and the further luminaire installation characteristic allows to improve the likeness in the selected list of the at least one suitable luminaire design between the first and/or second lighting site and the further lighting site. In another embodiment, the further lighting site needs at least one luminaire to be installed and the selecting of the list of the at least one suitable luminaire design allows optimizing common configuration parameters between luminaire designs for different lighting sites while maintaining the suitability to multiple lighting sites. It is to be noted that the further luminaire installation characteristic may be provided manually, and/or be extracted from available data, and/or originate from a database.
According to an exemplary embodiment, the first lighting site and/or the second lighting site corresponds to the location for installing, for the at least one luminaire, at least one luminaire head, optionally combined with an associated luminaire head bracket, to at least one existing base support.
In this way, luminaire installation characteristics may be provided directly based on the location of the at least one existing base support.
According to a preferred embodiment, the method further comprises:
obtaining at least one visual representation of the first lighting site and/or the second and/or a further lighting site;
extracting, from the at least one visual representation, the first and/or second and/or third and/or a further luminaire installation characteristic;
wherein the selecting of the list of the at least one suitable luminaire design is further based on the extracted first and/or second and/or third and/or further installation characteristic.
   By using as a base for extraction at least one visual representation of the first and/or the second and/or further lighting site, the filling out of luminaire installation characteristics to select the list of the at least one suitable luminaire design is greatly simplified, which improves the overall user-friendliness of the method. In an embodiment, a location of at least one base support to support at least one luminaire of the lighting site is visible in the at least one visual representation of the lighting site. By visible, it is meant that the location may be marked visually on site, or artificially a posteriori after an initial visual representation, for example a photo, of the lighting site has been obtained. The base support may correspond to a pole or a surface onto which a luminaire head may be provided, optionally with a luminaire head bracket. The base support need not be physically present on the lighting site in order for its location or the location of the luminaire to be visible on the lighting site.

Extraction methods based on the processing of the at least one visual representation are not described here but are known to the skilled person. The first and/or second and/or third and/or further luminaire installation characteristic may correspond to optical characteristics of the environment of the lighting site to be illuminated, and/or to dimensions relevant for the installation of a luminaire. In an embodiment, the extraction of the first and/or second and/or third and/or further installation characteristic may be followed by a manual correction or confirmation of the installation characteristic extracted.

More than one visual representation of the lighting site may be obtained and used for completeness. Since the filling out of the first and/or second and/or third and/or further luminaire installation characteristic is processed from the at least one visual representation, instead of manually as usually done in the prior art, the method is more user-friendly.

In an embodiment, the further lighting site may also be considered in addition to the first and/or second lighting site, and the above described steps may be applied similarly to at least one visual representation of the further lighting site and to the corresponding further luminaire installation characteristic.

According to an exemplary embodiment, the at least one visual representation is any one, or a combination, of: a photograph, a video, a map, a three-dimensional view, a street-level visualization.

The map of the lighting site may be a technical map of the lighting site, an architectural blueprint of the lighting site, a cadastral map, a topographic map, or an architectural project view of the lighting site.

According to a preferred embodiment, the at least one visual representation comprises an indication corresponding to a location of at least one luminaire base support within the first lighting site and/or the second lighting site.
In this manner, the extraction of the first and/or second and/or third and/or further luminaire installation characteristic may be more accurate due to the visually distinctly identified location of the at least one luminaire base support in its environment.
According to an exemplary embodiment, the at least one visual representation comprises a first and a second visual representation of the first lighting site and/or the second lighting site and/or the further lighting site, said first visual representation being different from said second visual representation; and the extracting of the first and/or second and/or third and/or further luminaire installation characteristic is based on the first and the second visual representations of the first lighting site and/or the second lighting site and/or the further lighting site.
In this way, multiple sources may be used in order to improve the precision of the extracted luminaire installation characteristic. In another embodiment, the plurality of visual representations may provide complementary information which, when processed, allows the extraction of the luminaire installation characteristic. Different or similar extraction methods may be used on the first and second visual representations of the first and/or second lighting and/or further lighting site to extract information, and optionally may be further processed. By combining different visual information, one may obtain luminaire installations characteristics not otherwise extractable.
According to a preferred embodiment, the method further comprises:
outputting an altered visual representation of the first lighting site and/or the second lighting site with at least one installed luminaire, based on the list of the at least one suitable luminaire design and on the at least one visual representation of the first lighting site and/or the second lighting site.
   In this manner, one can better visualize the aesthetics of the first and/or second lighting site with an installed luminaire from the list of the at least one suitable luminaire design. In one embodiment, when presented with the list, a user may pick a luminaire design from the list using a selection interface. Based on the at least one visual representation of the first and/or second lighting site, a composite altered visual representation of the lighting site may be processed to integrate the picked luminaire design as an installed luminaire on the lighting site. Preferably, the outputted altered visual representation is outputted via an AR (altered reality) device. Such visualization improves the user-friendliness of the implementation of the method by allowing another parameter, aesthetics, to be evaluated.

The steps of the method described above with respect to the first and/or second lighting site may be equally applied to the further lighting site for installing a luminaire.

The skilled person will understand that the hereinabove described technical considerations and advantages for embodiments of a method for selecting and sorting at least one luminaire design also apply to the below described corresponding computer program embodiments, mutatis mutandis.
According to a second aspect of the invention, there is provided a computer program. The computer program comprises instructions which, when the program is executed by a computer, cause the computer to carry out the method for selecting and sorting at least one luminaire design as hereinabove described.
The skilled person will understand that the hereinabove described technical considerations and advantages for embodiments of a method for selecting and sorting at least one luminaire design and a computer program also apply to the below described corresponding computer controlled system embodiments, mutatis mutandis.
According to a third aspect of the invention, there is provided a computer controlled system for selecting and sorting at least one luminaire design. The system includes:
a data entry means adapted to receive:
   a first luminaire installation characteristic associated to a first lighting site;
   a second luminaire installation characteristic associated to a second lighting site;
   wherein each of the first lighting site and the second lighting site corresponds to a location for installing at least one luminaire neighboring a pathway;
   optionally, a lighting regulation;
   a database comprising a plurality of luminaire designs;
a memory coupled to said data entry means for storing the first luminaire installation characteristic, the second luminaire installation characteristic, and said database comprising the plurality of luminaire designs, and optionally the lighting regulation;
a processor coupled to said memory;
a display coupled to said processor;
wherein the processor is further configured for:
   obtaining, from the memory, the first luminaire installation characteristic;
   obtaining, from the memory the second luminaire installation characteristic;
   optionally, associating a first weight to the first lighting site and a second weight to the second lighting site, said first weight and second weight being related to a comparison between the first lighting site and the second lighting site;
   optionally, obtaining, from the memory, parameters of the lighting regulation;
   selecting, based on the first luminaire installation characteristic, on the second luminaire installation characteristic, on the database with a plurality of luminaire designs, and, optionally, based on parameters of the lighting regulation, and/or, optionally, based on the first weight of the first lighting site, and on the second weight of the second lighting site, a list comprising for each lighting site at least one suitable luminaire design with at least one suitable configuration parameter of said plurality of luminaire designs, wherein a luminaire design may be the same or different for the first lighting site and the second lighting site;
   outputting the selected list of the at least one suitable luminaire design via the display;
   sorting the list based on a preferential parameter, preferably related to or based on a compatibility level with the first lighting site and the second lighting site, and, optionally, based on the first weight of the first lighting site and on the second weight of the second lighting site;
   outputting the sorted list of the at least one suitable luminaire design via the display.
      Preferred embodiments of the computer controlled system are disclosed in the claims. The technical merits of the embodiments of the method apply mutatis mutandis on the various embodiments of the computer program and of the computer controlled system. Also, the processor of the computer controlled system may be configured to perform any one of the above disclosed method steps.
      According to another aspect of the invention, there is provided an optical unit designing method. The optical unit designing method comprises the steps of:
obtaining at least one luminaire installation characteristic associated to a lighting site and a category of said lighting site;
calculating a desired lighting distribution for the lighting site based on the category of the lighting site, and on the at least one luminaire installation characteristic;
obtaining a closest optical unit comprising a plurality of optical elements, preferably lens elements, based on the desired lighting distribution, and on a database with a plurality of different optical elements, wherein the plurality of different optical elements comprises preferably a plurality of different lens elements;
obtaining a re-designed optical unit based on the desired lighting distribution, on the closest optical unit, and on the database with the plurality of different optical elements.
   In this manner, an optimized optical unit for a luminaire may be obtained. In order to do so, some of the plurality of optical elements may be identical.

By optical unit, it is meant one or more optical elements shaping the light emitted from the light source unit, e.g. the optical unit may comprise any one or more of the following optical elements: a lens element, reflector, backlight, filter, collimator, anti-glare frame.

More generally, an optical unit may comprise a single optical element or multiple optical elements. If the optical unit comprises multiple optical elements, those elements may be the same, e.g. two or more identical lens elements, or different, e.g. a lens element and a backlight or two different lens elements.

In general the optical unit may comprise any one of the following: a lens module, a reflector, a backlight, a prism, a collimator, a diffusor, a light shielding structure, and the like. Also, the optical unit may be combining multiple optical functions, e.g. a lens and a reflector function, or a collimator and a reflector function. The optical unit may comprise a plurality of optical sub-units, said optical sub-units being the same or different. This will allow combining different optical functions in the same footprint in a modular manner. For example, a first subset of light sources of a luminaire may be provided with a first set of optical sub-units of a first type, and a second subset of light sources may be provided with a second set of optical sub-units of a second type. This allows choosing suitable optical sub-units in function of the position of the light sources in the luminaire system. For example, light sources near the periphery of the optical unit may be provided with a different optical sub-unit compared to light sources provided in the centre of the optical unit, and/or light sources near the luminaire pole may be provided with a different optical sub-unit compared to light sources provided near a front end of a luminaire head of the luminaire system.

The optical unit may also comprise one or more light shielding structures complying with a certain glare classification, e.g. the G classification defined according to the CIE115:2010 standard and the G* classification defined according to the EN13201-2 standard. The light shielding structures may be configured for reducing a solid angle of light beams of the plurality of light sources by cutting off or reflecting light rays having a large incident angle, thereby reducing the light intensities at large angles and improving the G/G* classification of the luminaire system. Examples of light shielding structure are disclosed in patent applications PCT/EP2020/066221 and PCT/EP2019/074894, NL2025168 in the name of the applicant, which are included herein by reference.
Also, in order to reduce glare, a spacer element could be provided between a frame to which the optical unit is assembled and a support, such as a PCB, carrying the light sources. An example of a suitable spacer is disclosed in NL2025166.
In the context of the invention, a lens element of the optical unit may include any transmissive optical element that focuses or disperses light by means of refraction. It may also include any one of the following: a reflective portion, a backlight portion, a prismatic portion, a collimator portion, a diffusor portion. For example, a lens element may have a lens portion with a concave or convex surface for facing a light source, or more generally a lens portion with a flat or curved surface facing the light source, and optionally a collimator portion integrally formed with said lens portion, said collimator portion being configured for collimating light transmitted through said lens portion. Also, a lens element may be provided with a reflective portion or surface, referred to as a backlight element in the context of the invention, or with a diffusive portion.
A lens element may comprise a lens portion having an outer surface and an inner surface intended to face an associated light source. The outer surface may be a convex surface and the inner surface may be a concave or planar surface. Also, a lens element may comprise multiple lens portions adjoined in a discontinuous manner, wherein each lens portion may have a convex outer surface and a concave inner surface.
Preferably, the entire optical unit, e.g. an entire lens plate, is made of a transparent or translucent material.
In an embodiment, the optical unit may be a single optical plate with an array of optical elements of only one kind, or with a plurality of rows or columns with a first kind of optical elements and another plurality of rows or columns with a second kind of optical elements. In another embodiment, the optical unit may comprise two or more optical plates of a similar or different kind.

In yet another embodiment, the optical unit may comprise an optical plate with a plurality of optical elements arranged orderly in a manner different from an array, e.g. in a spiral, in a diamond pattern, a honeycomb pattern, concentrically, or arranged disorderly.

In a particular embodiment, the optical unit may be a single lens plate with an array of lens elements of only one kind, or with a plurality of rows or columns with a first kind of lens element and another plurality of rows or columns with a second kind of lens elements, or with different kinds of lens elements alternating within a row of the plurality of rows and/or within a column of the plurality of columns. In another embodiment, the optical unit may comprise two or more lens plates, or a lens plate with another optical plate, e.g. an anti-glare frame, an array of backlights, etc.

In still another embodiment, the optical unit may comprise a plurality of superposed optical plates, e.g. a lens plate superposed with a global filter plate, a plate of collimators superposed with a plate of backlights, etc.

The skilled person will understand that a plurality of optical elements may be combined freely as part of one or more optical plates, and that the one or more optical plates may also be disposed freely one with respect to the other in order to obtained a desired light distribution by the association of the light source unit and the optical unit.

By desired lighting distribution, it is meant a lighting distribution offering the optimal lighting conditions in terms of uniformity of the lighting and intensity of the lighting to users of the lighting site. Calculation of the theoretical desired lighting distribution is generally known by the skilled person.

In an embodiment, the database with the plurality of different optical elements may be stored on a server of a luminaire manufacturer. The plurality of optical elements, preferably lens elements, may be preferably organized in an array with a plurality of rows and a plurality of columns. A practical lighting distribution may be calculated for each different optical element in the database with the plurality of different optical elements. Each of the practical lighting distributions may be compared with the desired lighting distribution in order to find a closest practical lighting distribution whose difference with the desired lighting distribution is the smallest among the plurality of practical lighting distributions. The closest optical unit may be obtained by using optical elements associated with the closest lighting distribution.

By re-designing the closest optical unit, it is meant modifying by altering and/or adding optical elements of the closest optical unit such that the re-designed closest optical unit may have a lighting distribution even closer to the desired lighting distribution. In re-designing, one can limit an amount of modifications to the closest optical unit. For example, one can fix a maximum number of different additional optical elements to add to the closest optical unit. In another embodiment, the closest optical unit may be altered by using different kinds of optical elements instead of optical elements of one kind, and a number of kinds of optical elements may be limited. An optical unit comprising a plurality of optical plates of the same kind may thus be re-designed as a composition of optical plates of different kinds, or a new optical plate may be created comprising a plurality of optical elements of different kinds.

The obtaining of a re-designed optical unit may be done e.g. by using any one of the methods disclosed in PCT/EP2021/071200. For example, a frame may be used, and a plurality of optical modules may be provided to the frame. The re-designing may then be done by altering one or more optical modules to be included in the frame and/or by adding optical modules to be included in the frame. The optical modules of the re-designed optical unit may then be fixed in the frame using any suitable technique, e.g. by welding or by plastically reshaping a portion of the frame and/or of the optical module to cause a locking between the frame and the optical modules.

The plurality of optical modules may be picked from a storage comprising many different optical modules, and this picking may be based on the re-designed optical unit

According to another aspect of the invention, there is provided a functional unit designing method. The functional unit designing method comprises the steps of:
obtaining at least one luminaire installation characteristic associated to a lighting site and/or a category of said lighting site;
calculating one or more desired functionalities for the lighting site based on the category of the lighting site, and/or on the at least one luminaire installation characteristic;
obtaining a closest functional unit comprising a plurality of functional elements, e.g. optical elements or sensor elements, based on the desired functionalities, and on a database with a plurality of different functional elements, wherein the plurality of different functional elements comprises preferably a plurality of different optical elements and/or sensor elements and/or communication elements and/or signaling elements;
obtaining a re-designed functional unit based on the one or more desired functionalities, on the closest functional unit, and on the database with the plurality of different functional elements.

The preferred features disclosed above for optical units may be included generally in any units for use in a luminaire, e.g. units comprising non-optical modules.

For example, also non-optical modules may be assembled in a frame to provide an assembly for use in a luminaire. For example, a module may comprise a non-optical element such as a sensor, e.g. an environmental sensor such as a light sensor or an image sensor. Also, a frame may comprise a combination of optical and non-optical modules.

In a preferred embodiment, the above described steps of the method may be applied based on a first luminaire installation characteristic of a first lighting site and on a category of the first lighting site, and based on a second luminaire installation characteristic of a second lighting site and on a category of the second lighting site. In implementing the method in regards to the first lighting site and the second lighting site, one can obtain a list comprising, for each lighting site, at least one re-designed optical unit, wherein the at least one re-designed optical unit may be the same or different for the first lighting site and the second lighting site. By taking into account the first lighting site and the second lighting site, one can sort the list based on a number of common optical elements between the at least one re-designed optical unit for the first lighting site and the at least one re-designed optical unit for the second lighting site. Optionally, the sorting may also be based on a weight of the first lighting site and of the second lighting site. The aim of the sorting may be to obtain the highest number of optical elements in common between lighting sites in order improve the overall logistics of a future installation. The skilled person will understand that the technical merits of the embodiments of the method for selecting and sorting at least one luminaire design apply, mutatis mutandis, on the various embodiments of the optical unit designing method, and that both methods may be applied jointly without restriction.
According to a further aspect of the invention, there is provided a method for selecting and sorting at least one functional pole design and/or street furniture design, e.g. a modular pole with multiple functional modules arranged one above the other, or a pole with a luminaire head and/or other functional optical or non-optical modules. The method comprises the following steps preferably performed by a computer means, preferably performed in the order specified:
obtaining a first installation characteristic associated to a first site;
obtaining a second installation characteristic associated to a second site;
wherein each of the first site and the second site corresponds to a location for installing at least one pole assembly and/or street furniture neighboring a pathway;
optionally, associating a first weight to the first site and a second weight to the second site, said first weight and second weight being related to a comparison between the first site and the second site;
selecting, based on the first installation characteristic, on the second installation characteristic, on a database with a plurality of pole designs, and, optionally, based on parameters of a regulation, and/or, optionally, based on the first weight of the first site and on the second weight of the second site, a list comprising for each site at least one suitable pole design with at least one suitable configuration parameter of said plurality of pole designs, wherein a pole design may be the same or different for the first site and the second site;
sorting the list based on a preferential parameter, preferably based on or related to a compatibility level with the first site and the second site, and, optionally, based on the first weight of the first site and on the second weight of the second site.
   Preferred features set out above for selecting and sorting at least one luminaire design, may be used in a similar manner for selecting and sorting at least one pole design or street furniture design, wherein a pole design refers to a design of any pole-like structure including optical and/or non-optical functional modules and wherein street furniture design refers to a design of any kind of street furniture optionally including one or more functional modules.
   The regulation may be a lighting regulation but could also be another regulation such as a sensing regulation and/or data management/storing regulation (e.g. GDPR), notably if the pole assembly or street furniture comprises functional modules like sensor and/or communication devices.
   A functional module may be e.g. a functional pole module which is part of a modular pole, or a functional module with a housing attached to an external surface of a support pole of the lamp post, Examples of functional components which may be included in a functional module, an in particular in a functional pole module, are any one or more of the following:
power management circuitry, preferably power management circuitry configured to manage the provision of power to multiple lamp posts, preferably at least three lamp posts, e.g. more than ten lamp posts. In such embodiments power connection cables pass from the pole module through the support pole to other lamp posts, e.g. underground;
telecommunication circuitry, such as base station circuitry;
audio system management circuitry;
a display;
an antenna;
WiFi circuitry, wherein an antenna for receiving WiFi signals may be integrated either in the pole module or in a separate antenna module;
charger circuitry, e.g. phone charger circuitry or vehicle charger circuitry;
an environmental sensor such as a microphone, or a detector of CO2, NOx, smoke, etc., and the associated circuitry;
a human interface device (HID) and the associated circuitry, e.g. a camera, a loudspeaker, a button, a touch screen, etc.
repeater circuitry, e.g. a WiFi repeater;
a radar sensor;
a sign, such as a publicity banner;
a water discharge device, such as a shower head, a sprinkler, a water sprayer, etc;
a trash bin;
a socket, such as an electrical socket.
   An example of a pole assembly in the form of a modular pole with pole modules is disclosed in EP 3 076 073 B1 in the name of the applicant, which is included herein by reference. The lamp post comprises a plurality of pole modules e.g. mounted on a support pole. The pole modules are connected to one another by respective pole module connectors. Further it is known to include additional functionalities, either in the modular lamp post itself or in a separate cabinet adjacent a lamp post. Examples of such modular lamp posts are disclosed in WO 2019/043045 A1, WO 2019/043046 A1 and WO2020/152294 in the name of the applicant, which are included herein by reference. An example with a camera pole module is disclosed in WO 2019/092273 A1 and WO 2021/094612 in the name of the applicant, which are included herein by reference.

### BRIEF DESCRIPTION OF THE FIGURES

This and other aspects of the present invention will now be described in more detail; with reference to the appended drawings showing a currently preferred embodiment. Like numbers refer to like features throughout the drawings.

FIG. 1 illustrates schematically an exemplary embodiment of a method for selecting and sorting at least one luminaire design;

FIG. 2 depicts an outline of a lighting site according to an exemplary embodiment of the invention;

FIGS. 3A-3B depict two different views of a list of at least one luminaire design obtained according to exemplary embodiments of the invention;

FIG. 4 depicts a visual representation of a lighting site according to exemplary embodiments of the invention;

FIG. 5 depicts a visual representation of a plurality of lighting sites according to exemplary embodiments of the invention;

FIGS. 6A-6C illustrate schematically a view of a selected list, and two views of a sorted list, respectively, according to exemplary embodiments of the invention;

FIG. 7 illustrates a flow chart of an optical unit designing method according to exemplary embodiments of the invention.

### DESCRIPTION OF EMBODIMENTS

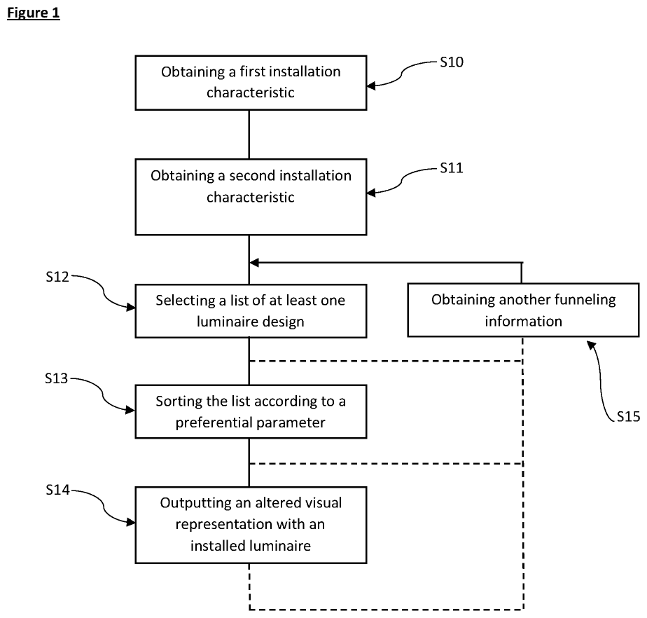

FIG. 1 illustrates schematically an exemplary embodiment of a method for selecting and sorting at least one luminaire design according to the present invention.

The method of the present invention allows selecting and sorting a list comprising at least one luminaire design suitable for a first lighting site and a second lighting site. The lighting site may correspond to any space to be illuminated with a location for installing at least one luminaire. The lighting site may be defined following different categories, each category corresponding to a different illumination scheme and/or type of a pathway within and/or neighboring the lighting site that can be taken by vehicles and/or pedestrians. The pathway may be a pathway on a lighting site suitable for outdoor luminaires. By lighting site for outdoor luminaires, it is meant roads, tunnels, industrial plants, stadiums, airports, harbors, rail stations, campuses, parks, cycle paths, pedestrian paths, or pedestrian zones for example, and outdoor luminaires can be used notably for the lighting of an outdoor area, such as roads and residential areas in the public domain, private parking areas and access roads to private building infrastructures, etc. In other embodiments according to the invention, the pathway may be located indoors, such as in a warehouse or an industry hall.

Since the method is related to a first and a second lighting site corresponding to locations for installing at least one luminaire neighbouring the pathway, several situations may be considered regarding the extent of the installation. Depending on the situation, a complete luminaire may already be installed on the lighting site and there is an interest in replacing it or at least replacing part of it, or only part of the luminaire is present on the lighting site, e.g. the base support of the luminaire is already mounted or the location where the base support will be is identifiable. Alternatively, the position of the at least one luminaire and its base support within the lighting site has also to be determined.

In an embodiment, the first lighting site and/or the second lighting site may comprise at least five luminaires to be installed, preferably at least ten luminaires to be installed. It is to be noted that the lighting site corresponds to a category of lighting site to be illuminated defined according to a type of illumination scheme required and/or according to the type of the pathway within and/or neighboring the related lighting site. So, the lighting site is not restricted to a geographical location and may be divided into several geographical locations. For example, in an embodiment, the first lighting site corresponds to a lighting site neighboring a street and may be divided into five luminaires to be installed in a first street section and two luminaires to be installed in a second street section, and the second lighting site corresponds to a pedestrian crossing with two luminaires to be installed on each side of the crossing.

As can be seen in the embodiment of FIG. 1, the method comprises the step S10 of obtaining a first luminaire installation characteristic associated to a first lighting site. The lighting site may be defined following different categories, each category corresponding to a different illumination scheme and/or type of the pathway within and/or neighboring the related lighting site. The lighting site may be any one of: a standard motorway section, a pedestrian crossing, a pedestrian zone, a square, a bicycle lane, a standard road section, a road crossing, a conflict zone, a marketplace, a bridge, an industry hall, an airport, a stadium, a warehouse, etc. Generally, types of pathways are defined according to the lighting regulations, or standards, of the geographical area where the lighting site is located, such as EN13201, IES RP-8, CIE 115.

The first luminaire installation characteristic may correspond to optical characteristics of the environment of the first lighting site to be illuminated, and/or to dimensions relevant for the installation of a luminaire. The plurality of luminaire designs in the database comprising the plurality of luminaire designs may each be associated to one or more configuration parameters from which the suitability to the optical characteristics of the first lighting site to be illuminated and/or to the dimensions of the first lighting site relevant for the installation of a luminaire may be deducted. The suitability of the luminaire design arises from the inclusion in the luminaire design of at least one suitable configuration parameter. The at least suitable configuration parameter may correspond to a physical parameter of the luminaire design, i.e. mechanical parameters, e.g. luminaire head fixation method, luminaire head housing luminaire compartments accesses, luminaire family, and/or optical parameters, e.g. average illuminance of a luminaire head, lighting distribution of the luminaire head, glaring index of the luminaire head, transversal uniformity of the emitted light, longitudinal uniformity of the emitted light, photometric accessories, and/or electrical parameters, e.g. power consumption, type of electrical connections, mains connections, type of driver, lamp/led type and wattage, lighting lifetime, and/or installation parameters, e.g. spacing, height, secondary functional unit.

In an embodiment, the obtaining of the first luminaire installation characteristic may comprise the steps of: scanning a QR code label provided to a pole of a luminaire to be retrofitted on the first lighting site; extracting data related to the first luminaire installation characteristic based on the scanned QR code. Indeed, luminaires on the first lighting site may be provided each with at least one QR code, said at least one QR code being linked to a database storing data, such as configuration data, installation data, environment data, of the corresponding luminaire.

In another embodiment, the obtaining of the first luminaire installation characteristic may be achieved by performing measurement on the first lighting site.

In yet another embodiment, the obtaining of the first luminaire installation characteristic may be achieved by retrieving data from an infrastructure database storing data related to pathways on a national level, regional level, and/or city level.

In still another embodiment, the obtaining of the first luminaire installation characteristic may comprise the steps of: obtaining at least one visual representation of the first lighting site; and extracting, from the at least one visual representation, the first luminaire installation characteristic. Extraction methods based on the processing of the at least one visual representation are not described here but are presumably known to the skilled person. The at least one visual representation may be any one, or a combination, of: a photograph of the lighting site, a video of the lighting site, a map of the lighting site, a three-dimensional view of the lighting site, a street-level visualization of the lighting site. In various embodiments, the map of the lighting site may be a technical map of the lighting site, an architectural blueprint of the lighting site, a cadastral map, a topographic map, or an architectural project view of the lighting site.

A plurality of visual representations of the lighting site may also be obtained. In an embodiment, the plurality of visual representations may be of the same kind and represent different viewpoints of the lighting site. In another embodiment, the plurality of visual representations may comprise visual representations of different kinds.

In a computer controlled system implementing the method, the first luminaire installation characteristic and/or the at least one visual representation may be received on a data entry means and stored in a memory for further processing. The data entry means may comprise at least one interface for reading a storage medium onto which the first luminaire installation characteristic and/or the at least one visual representation has been stored. The storage medium may be a local storage medium of the computer controlled system, e.g. a hard drive, a buffer memory, or may be a remote storage medium. The first luminaire installation characteristic and/or the at least one visual representation may be obtained by a processor of the system from the memory. In an embodiment, the first luminaire installation characteristic and/or the at least one visual representation may be obtained or retrieved from the storage medium based on an address inputted by the user, said address being associated to a location of the first lighting site and linked to at least one corresponding visual representation of the first lighting site.

In an embodiment, the extraction of the first luminaire installation characteristic may be based on a plurality of visual representations. The plurality of visual representations may be used in order to improve the precision of the extracted first luminaire installation characteristic. In another embodiment, the plurality of visual representations may provide complementary information which, when processed, allows the extraction of the first luminaire installation characteristic. Different extraction methods may be used on the various visual representations of the lighting site to extract information, and optionally may be further processed. By combining different visual information, one may obtain luminaire installations characteristics not otherwise extractable. Additionally or alternatively, the extraction may take into account data stored in a database relevant to the first luminaire installation characteristic associated to the first lighting site.

As can be seen in the embodiment of FIG. 1, the method comprises the step S11 of obtaining a second luminaire installation characteristic associated to a second lighting site.

Embodiments of step S11 are similar to embodiments of step S10 as described above. The first luminaire installation characteristic and the second luminaire installation characteristic may be of a similar or different type for the first and the second lighting sites.

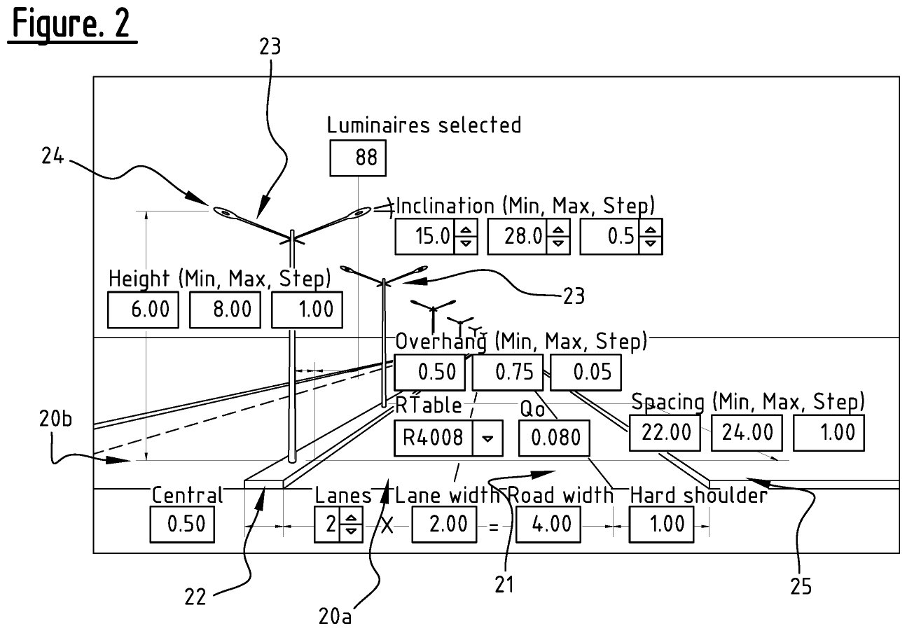

The luminaire installation characteristic may correspond to optical characteristics of the environment of the lighting site to be illuminated, and/or to dimensions relevant for the installation of a luminaire More detailed embodiments of the first and/or second luminaire installation characteristic will be described with reference to FIG. 2. In an embodiment, the obtaining of the first and/or second installation characteristic may be followed by a manual correction or confirmation of the at least one luminaire installation characteristic obtained.

Optionally, the method may comprise the step of associating a first weight to the first lighting site and a second weight to the second lighting site, said first weight and second weight being related to a comparison between the first lighting site and the second lighting site. To each lighting site may correspond a certain number of luminaires to be installed. These numbers may be used to determine a weight of the corresponding lighting site in the overall installation project. Additionally or alternatively, the weight of the corresponding lighting site may be determined based on an expected electricity consumption of the lighting site relative to the overall expected electricity consumption of all lighting sites. The determined weights may then be optionally used when selecting and/or sorting the list of the at least one suitable luminaire design for each lighting site.

As can be seen in the embodiment of FIG. 1, the method comprises a step S12 of selecting, based on the first luminaire installation characteristic, on the second luminaire installation characteristic, and on a database with a plurality of luminaire designs, a list comprising for each lighting site at least one suitable luminaire design with at least one suitable configuration parameter of said plurality of luminaire designs, wherein a luminaire design may be the same or different for the first lighting site and the second lighting site.

By suitability, it is meant the ability for the luminaire design to satisfy some lighting regulations, e.g. a public road lighting standard such as EN 13201, IES RP-8, CIE 115, respective to the environment of the lighting site, thereby allowing for an illumination giving a visibility above a predetermined level for users of the lighting site, as well as giving a predetermined illumination safety, e.g. illumination intensity below a blinding intensity, light emitted within a certain arc to avoid glaring angles. The suitability of the luminaire design arises from the inclusion in the luminaire design of at least one suitable configuration parameter. The at least suitable configuration parameter may correspond to a physical parameter of the luminaire design, i.e. mechanical parameters, e.g. luminaire head fixation method, luminaire head housing, luminaire compartments accesses, luminaire family, and/or optical parameters, e.g. average illuminance of a luminaire head, lighting distribution of the luminaire head, glaring index of the luminaire head, transversal uniformity of the emitted light, longitudinal uniformity of the emitted light, photometric accessories, and/or electrical parameters, e.g. power consumption, type of electrical connections, mains connections, type of driver, lamp/led type and wattage, lighting lifetime, and/or installation parameters, e.g. spacing, height, secondary functional unit.

Additionally, a compatibility level of the luminaire design respective to its corresponding lighting site may be defined. The compatibility level refers not only to the suitability, i.e. whether it is suitable or not to illuminate the lighting site, but is also a measure of how much the configuration parameters of the luminaire design are suited to the at least one luminaire installation characteristic of the lighting site in order to obtain desired illumination and working conditions of the luminaire design. For example, a luminaire design could be suitable for a lighting site in terms of illumination, but would need to be driven at a high power with respect to nominal working conditions in order to do so; thereby decreasing the compatibility level of the luminaire design respective to the lighting site.

The selecting of the list of the at least one suitable luminaire design may, optionally, be based on parameters of a lighting regulation, and/or on the first weight of the first lighting site and on the second weight of the second lighting site.

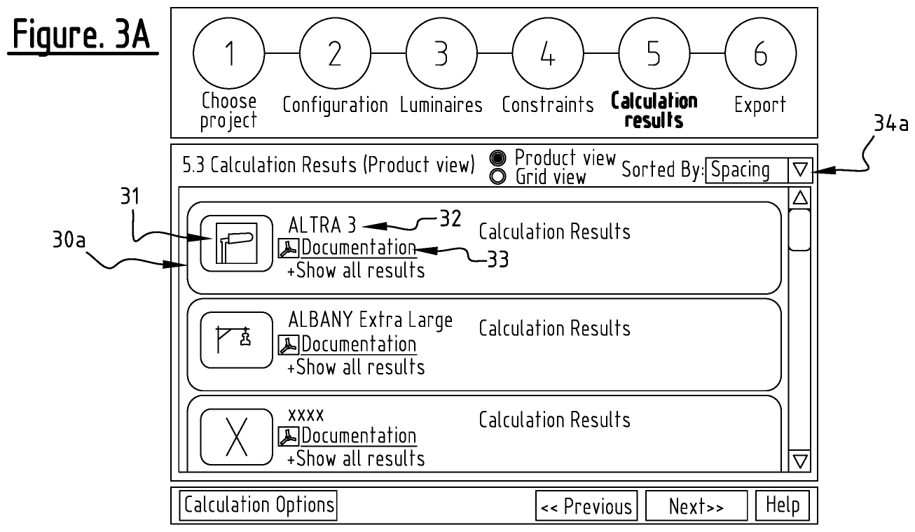

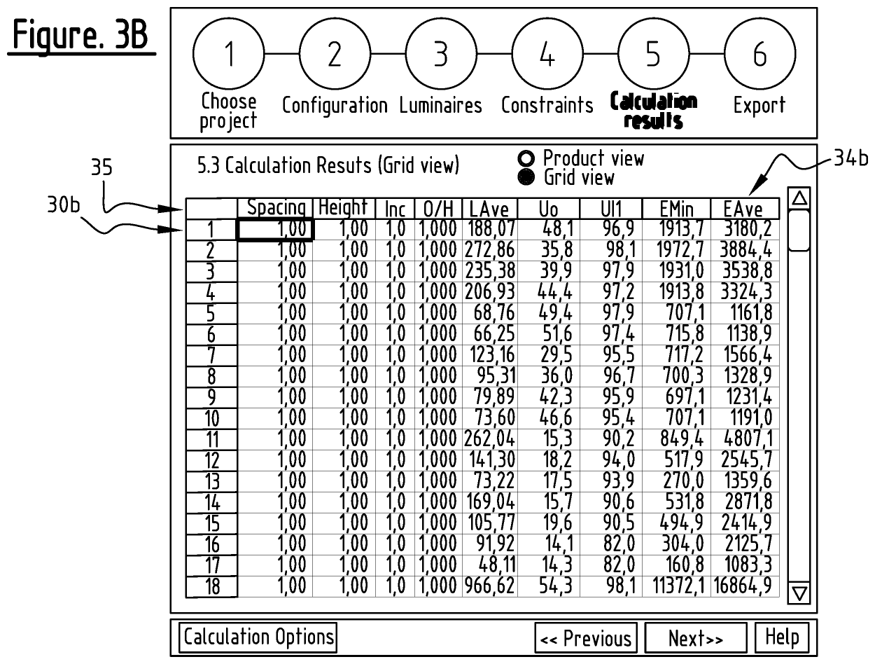

In the computer controlled system, the database of the plurality of luminaire designs may be received by the data entry means and stored in the memory of the system. In an embodiment, the database of the plurality of luminaire designs may be available on a server of a luminaire producer. The list may be obtained by the processor of the system and displayed on a display of the system. Each luminaire design on the list may be associated with a summary of the luminaire design with its configuration parameters, e.g. spacing, height, average illuminance of a luminaire head, transversal uniformity of the emitted light, longitudinal uniformity of the emitted light, glaring index of the emitted light, luminaire family, lamp/led type and wattage, commercial brand of luminaire parts, driver type, lighting light distribution, luminaire working temperature, lighting lifetime, luminaire head fixation method, power consumption, type of electrical connections, mains connection, type of driver, luminaire head housing, luminaire compartment accesses, lighting distribution of the luminaire head, photometric accessories, secondary functional unit, etc. More detailed embodiments of views of the list will be described with reference to FIGS. 3A-3B.

To select the list of the at least one suitable luminaire design, the first and/or second luminaire installation characteristic may be compared to the configuration parameters associated to each of the plurality of luminaire designs in the database of luminaire designs to check for a positive correspondence. The positive correspondence may be an indicator of the suitability of the corresponding luminaire design. By an elimination process, the list of at least one suitable luminaire design can be selected. In an embodiment, no suitable luminaire design can be selected and the computer controlled system may display a manual input interface to input the first and/or second luminaire installation characteristic manually; or the computer controlled system may suggest the first and/or second installation characteristic to be reset to avoid for the list to be void, or may suggest the first and/or second luminaire installation characteristic to be modified.

For each lighting site, there may be one or more suitable luminaire design selected. In an embodiment, there may be at least two luminaire designs suitable, respectively, for at least two lighting sites, having at least one similar configuration parameter; thereby allowing optimizing the overall logistics of the luminaire installation project as well as potentially reducing the number of spare parts to be kept in stock for maintenance. Preferably, the at least one similar configuration parameter comprises at least one of: a luminaire family, a luminaire head housing, a light source unit, an optical unit, a luminaire driver.

For example, the at least one similar configuration parameter may be a luminaire family. By luminaire family, it is meant a group of luminaires derived from a common luminaire platform and being made by similar production processes, or having similar physical characteristics. By light source unit, it is meant the light source of the luminaire head comprising a e.g. predetermined number of LEDs, said LEDs provided to a predetermined support. By optical unit, it is meant optical elements shaping the light emitted from the light source unit, e.g. an array of lens elements, reflectors, backlights, filters, collimators anti-glare frames.

As can be seen in the embodiment of FIG. 1, the method comprises the step S13 of sorting the list of the at least one suitable luminaire design based on a preferential parameter. The preferential parameter may be any one of: a compatibility level with a lighting site, a luminaire family, an installation budget, a number of luminaires to be installed, a maximum wattage of the at least one luminaire to be installed, a type of light source, a total cost of ownership, a luminaire managing option, an aesthetical consideration, a number of luminaires to be installed, a glaring index, a commercial brand, a number of parts of a luminaire design, a lighting uniformity, a lighting intensity, an average illuminance, a lifetime, a method of installation, an operating temperature, a recycling factor, a certificate, an electrical connection type, a secondary functionality of the luminaire, a compliancy with a lighting regulation, a power consumption per kilometer, etc. For example, the certificate may be related to an ecological label of a manufacturing company and/or of luminaire parts of the luminaire design, an IP-rating of the luminaire design, a resistance rating to shocks and/or vibrations, etc.

The list will be sorted in rank of correspondence with the selected preferential parameter. The preferential parameter used for the sorting of the list may be a single parameter attributed by default, a preferential parameter selected by a user, or a plurality of preferential parameters. Also, the one ore more preferential parameters may be associated with a tolerance level. By tolerance level, it is meant an indication of how much a value of the preferential parameter may be modified for a given selected luminaire design to end in the sorted list.

In an embodiment, there may be two luminaire designs suitable for the first lighting site belonging to different luminaire families, and one luminaire design suitable for the second lighting site of the same luminaire family as one of the luminaire designs associated to the first lighting site. The preferential parameter may be the luminaire family and the sorted list may include the two luminaire designs sharing the same luminaire family. In another embodiment, the sorted list includes the same luminaire design for both the first lighting site and the second lighting site. In preferred embodiments, the total number of different luminaire designs in the sorted list may be less than the number of lighting sites.

In the computer controlled system, the preferential parameter may be selected through an input interface via an inputting means of the system. The inputting means may be any one of: a touch-sensitive interface, a keyboard, a button, a mouse, etc. In an embodiment, the view of the list displayed on the display of the system may comprise an interface to select the one or more preferential parameter among a preset list of preferential parameters.

In an embodiment, the step S13 may further comprise the steps of providing an input corresponding to another preferential parameter relative to the plurality of luminaire designs; and sorting the list of the at least one suitable luminaire design further based on the another preferential parameter. Each of the plurality of preferential parameters may be weighted according to a picking order, said picking order reflecting the order of importance amongst the plurality of preferential parameters. Also, each of the plurality of preferential parameters may be associated with a tolerance level. By tolerance level, it is meant an indication of how much a value of the preferential parameter may be modified for a given selected luminaire design to end in the sorted list. Additionally or alternatively, an interface may be outputted to allow a user to select the preferential parameter and/or the another preferential parameter.

As can be seen in the embodiment of FIG. 1, the method comprises the optional step S14 of outputting an altered visual representation of the first and/or second lighting site with at least one installed luminaire, based on the list of the at least one suitable luminaire design and on the at least one visual representation of the lighting site. Based on the at least one visual representation of the first and/or second lighting site, a composite altered visual representation of the lighting site may be processed to integrate the picked luminaire design as an installed luminaire on the lighting site. The outputted altered visual representation may be of a similar or different kind as the at least one visual representation. Preferably, the outputted altered visual representation is outputted via an AR (altered reality) device.

In an embodiment of the computer controlled system, a selection interface may be displayed on the display of the system, and a user of the system may input via an inputting means a selected luminaire design part of the list of the at least one suitable luminaire design. After the selection, the system may output an altered visual representation. The list of the at least one suitable luminaire design and the altered visual representation may be outputted via similar or different outputting means, e.g. two different displays included in the system.

As can be seen in the embodiment of FIG. 1, the method comprises the optional step S15 of obtaining another funneling information. The step S15 may be executed before step S12, and/or after step S12, and/or step S13, and/or step S14. The another funneling information may allow to further reduce the number of luminaire designs in the selected list of the at least one suitable luminaire design. Indeed, the another funneling information may be provided when iterating or reiterating step S12 of the method to be taken into account. However, the selected list is not necessarily reduced due to the another funneling information.

In an embodiment, the step S15 may comprise obtaining, from a regulation database, a lighting regulation associated to the first and/or second lighting site. The lighting regulation may correspond to a legal obligation or recommendation based on the kind of the identified pathway, the amount of traffic, the type of users of the pathway, etc. In an embodiment, the obtaining of the lighting regulation may be based on the geo-coordinates of the lighting site or part of the lighting site. Additionally or alternatively, the obtaining of the lighting regulation may be at least partially based on the obtained luminaire installation characteristic, e.g. the number of lanes of the pathway. In an embodiment, the obtaining of the lighting regulation may be followed by a manual correction or confirmation of the lighting regulation associated to the lighting site. Also, the obtaining of the lighting regulation may be achieved by a manual entry.

The regulation database may be a nation-wide database, a region-wide database, a city-wide database, or a local-wide database. In an embodiment, the regulation database may be stored in the memory of the system and the obtaining of the lighting regulation may be achieved by reading the regulation database in the memory. In another embodiment, the system may further comprise a communication means configured for communication with the regulation database located remotely.

In an embodiment, the step S15 may comprise obtaining, from a stock database, a list of available luminaire parts. In an embodiment, the stock database may be stored in the memory of the system and the obtaining of the list of available luminaire parts may be achieved by reading the stock database in the memory. In another embodiment, the system may further comprise a communication means configured for communication with the stock database located remotely. In this way, the selected list of the at least one suitable luminaire design in step S12 reflects an actual product availability.

Indeed the luminaire design may comprise a certain number of luminaire parts, e.g. a luminaire driver, a lighting unit, an optical unit, ESD, SPD, fuses, a luminaire head housing, sensing means, to be gathered with various parts being essential or interchangeable. The availability of luminaire parts may change the overall characteristics of a luminaire design. The stock database may be luminaire parts available in a stock of a local provider, in a stock of a luminaire producer, in a catalogue of products, or in a personal stock. The availability may be further distinguished between available in stocks, discontinued, in production, and/or with a time indication of the availability on the lighting site for installation. The list of available luminaire parts may also comprise a quantity of available luminaire parts, an end-of-life date of available luminaire parts, a manufacturing country of the luminaire parts, an ecological label of the luminaire parts. In an embodiment, the selecting of the list of the at least one suitable luminaire design may be based on luminaire designs favoring available luminaire parts whose quantity in stocks is high, which are subject to a special price offer, and/or which are close to the end-of-life date.

In an embodiment, the step S15 may comprise providing an input corresponding to a third luminaire installation characteristic of the first lighting site and/or the second lighting site. The selecting of the list of the at least one suitable luminaire design may be further based on the third luminaire installation characteristic. This third luminaire installation characteristic may be provided from various sources. For example the third luminaire installation characteristic may be provided via a manual input by a user using an inputting means, e.g. a keyboard. Alternatively, the third luminaire installation characteristic may originate from a database of known luminaire installation characteristics and/or based from measured data.

In an embodiment, the step S15 may comprise the selecting of the list of the at least one suitable luminaire design further based on a further luminaire installation characteristic of a further lighting site. The first and second luminaire installation characteristics and the further luminaire installation characteristic may be of similar or different kinds. In one embodiment, the further lighting site does not need to have luminaires installed and the further luminaire installation characteristic allows improving the likeness in the list of the at least one suitable luminaire design between the first and/or second lighting site and the further lighting site. In another embodiment, the further lighting site needs at least one luminaire to be installed and the sorting of the list of the at least one suitable luminaire design allows optimizing common configuration parameters between luminaire designs for different lighting sites while maintaining the suitability to multiple lighting sites. It is to be noted that the further luminaire installation characteristic may be provided manually, and/or extracted from available data, and/or originate from a database and/or from measured data.

In an embodiment, the step S15 may obtain the another funneling information from the sorted list after step S13, and the reiteration of step S12 may allow to remove from the list at least one of the luminaire design such that a number of luminaire designs per lighting site is decreased in the sorted list.

In an embodiment, the step S15 may obtain the another funneling information via an input from the user of the computer controlled system after a negative appreciation of the outputted altered visual representation of step S14.

In an embodiment, the step S12 may be followed by another step comprising the provision of a purchase selection interface. The purchase selection interface may allow the user, after selection of the at least one desired luminaire design from the sorted list of the at least one suitable luminaire design, to conclude by ordering the at least one desired luminaire design for installing on the lighting site.

In an embodiment, the step S13 may be followed by another step comprising the provision of a report to the user, said report comprising the list of the at least one suitable luminaire design, each of the at least one luminaire design being accompanied by its respective summarized characteristics. The summarized characteristics may comprise a product image of the luminaire design, configuration parameters of the luminaire design, links to documents related to the luminaire design, managing options, secondary functional unit options such as possibilities for additional sensors to be installed, or commercial information.

FIG. 2 depicts an outline of a lighting site according to an exemplary embodiment of the present invention. From the lighting site, various luminaire installation characteristics may be obtained which are relevant for processing the selection of a suitable luminaire design.

The standard motorway section lighting site depicted in the embodiment of FIG. 2 comprises at least one pathway, more particularly two roads 20a, 20b in the embodiment of FIG. 2. Each of the two roads 20a, 20b may comprise a given number of lanes 21, two lanes 21 for each of the roads 20a, 20b. Depending on the configuration of the pathway, different vehicles may use said pathway. The roads 20a, 20b of FIG. 2 are adapted only for motor-driven vehicles. Depending on the configuration of the pathway, a direction of traffic may be identified, with the traffic direction being similar or different for each lane 21. The road 20a on the right side of FIG. 2 may have a traffic direction away from the viewer with its two lanes 21 having similar traffic directions, and the road 20b on the left side of FIG. 2 may have a traffic direction towards the viewer with its two lanes 21 having similar traffic directions. The two roads 20a, 20b may be separated by a central element 22 with a given width. The roads 20a, 20b and/or lanes 21 may each have a specific width in a direction perpendicular to the traffic direction.

The lighting site may have at least one luminaire 23 to be installed or retrofitted, a plurality of luminaires 23 in the embodiment of FIG. 2. Each of the plurality of luminaires 23 may comprise one of more luminaire head 24, for example two luminaire heads 24 per luminaire 23. Two luminaires 23 may be located at a specific spacing from each other. In the case of a standard motorway section, for example, this spacing may be a regular interval between each of the luminaires 23.

The luminaire 23 may comprise a base support, e.g. a pole, onto which the luminaire head 24 is mounted, optionally in association with a luminaire head bracket. Various dimensions may be identified with respect to the luminaire 23: a height of the base support, an overhang of the luminaire head 24 with respect to the base support, an inclination of the luminaire head 24 with respect to a horizontal direction, a lateral dimension of a hard shoulder of the pathway, an arrangement pattern of a group of luminaires including the at least one luminaire, a location of the at least one luminaire base support respective to the one or more circulation directions. Also an optical characteristic of the surface to be illuminated may be obtained, e.g. the reflective optical characteristics of the surface.

FIGS. 3A-3B depict two different views of a list of suitable luminaire designs obtained according to exemplary embodiments of the present invention.

FIG. 3A depicts a product view of the list of the at least one suitable luminaire design obtained according to the method of the present invention. FIG. 3B depicts a grid view of the list of the at least one luminaire design obtained by the method of the present invention. In the embodiments of FIGS. 3A-3B, the list may be outputted via a display of a computer controlled system. Via an inputting means of the system, a user of the system may alternate between the view of FIG. 3A and the view of FIG. 3B.

FIG. 3A presents the list of the at least one suitable luminaire design in a marketing view which is more user-friendly. A row of the list may comprise one luminaire design, the luminaire design of the row being associated with one lighting site. Each of the at least one suitable luminaire design part of the list is displayed in a separate presentation box 30a of the list, said presentation box 30a occupying a row. The lighting site having more than one suitable luminaire designs may be displayed as a corresponding plurality of separated presentation boxes 30a organized in a column of one or more rows. For example, the first and second presentation boxes 30a, the first and second rows, may correspond to suitable luminaire designs for a first lighting site, and the third presentation box 30a, the third row, may correspond to a suitable luminaire design for the second lighting site.

Various information are associated to each luminaire design and presented in the presentation box 30a. On the left side of the box, a picture 31 of the luminaire design depicts a real view of the product corresponding to the luminaire design. The picture 31 of the luminaire design is accompanied on its right side by a luminaire name 32, and a link 33 to a PDF documentation of the luminaire design. Alternatively or additionally, the information associated to each luminaire design may comprise a three-dimensional view of the luminaire design and/or a link, e.g. coded as a QR code or a barcode, to an application allowing an altered reality visualization of the associated luminaire design. The altered reality visualization may comprise a simulated visualization of the installed luminaire design, an external view of a luminaire head, and/or an internal view of the luminaire head.

The list of FIG. 3A can be sorted according to a selected preferential parameter 34a. The preferential parameter 34a may be selected via a selection interface, e.g. a drop-down menu, displayed on the display of the system. The sorting in FIG. 3A may be achieved based on any one of the following parameters: a compatibility level with a lighting site, an installation budget, a number of luminaires to be installed, a maximum wattage of the at least one luminaire to be installed, a type of light source, a luminaire managing option, an aesthetical consideration, a number of luminaires to be installed, a number of parts of a luminaire design, an average illuminance of a luminaire head (on the pathway or on a side of the pathway), a luminaire family, a lighting uniformity, a lighting intensity, a glaring index of the emitted light, a commercial brand, driver type, a lighting light distribution, an operating temperature, a recycling factor, a certificate, an electrical connection type, a secondary functionality of the luminaire; a lifetime, a total cost of ownership, a method of installation, a compliancy with a lighting regulation, a power consumption per kilometer, etc.

FIG. 3B presents the list of the at least one luminaire design in a more comprehensive view showing different configuration parameters as well as other parameters of each luminaire design. The luminaire design parameters 35 are corresponding to the columns of the grid view of FIG. 3B. Each row of the grid view, apart from the first one, corresponds to a different luminaire design 30b. A row of the list in FIG. 3B may correspond to one luminaire design, each luminaire design associated with one lighting site. Each of the at least one luminaire design part of the list is displayed in a separate luminaire design row 30b of the list. The lighting site having more than one suitable luminaire designs may be displayed as a series of rows corresponding to the plurality of suitable luminaire designs 30b. Each lighting site may be separated from the other one with a pronounced marking.

The luminaire design parameters 35 may be: a spacing, a height, a luminaire family, an overhang, an average illuminance of an emitted light (on the pathway or on a side of the pathway), a transversal uniformity of the emitted light, a longitudinal uniformity of the emitted light, an average enlightenment of the emitted light, a glare threshold index of the emitted light, luminaire name, a lamp/led type and wattage, brand of luminaire parts, driver type, a light distribution, a luminaire working temperature, a lighting life time, a luminaire class, a luminaire total cost of ownership, a luminaire installation method, a compliancy with a lighting regulation, a power consumption per kilometer, etc. The list presented in the grid view of FIG. 3B may be sorted according to the luminaire design parameters 35 of each column. In an embodiment, a tooltip may be displayed with various information in a similar manner as the presentation box 30a of FIG. 3A. The tooltip may be displayed when a mouse hovers the row of the luminaire design 30b in the grid view.

The skilled person will understand that in other embodiments, the sorting in FIGS. 3A-3B may alternatively be based on any one of previously cited configuration parameters, and/or commercial information of the luminaire design. For example, the sorting may be based on a certificate of the luminaire design; the certificate may be related to an ecological label of a manufacturing company and/or of luminaire parts of the luminaire design, an IP-rating of the luminaire design, a resistance rating to shocks and/or vibrations, etc.

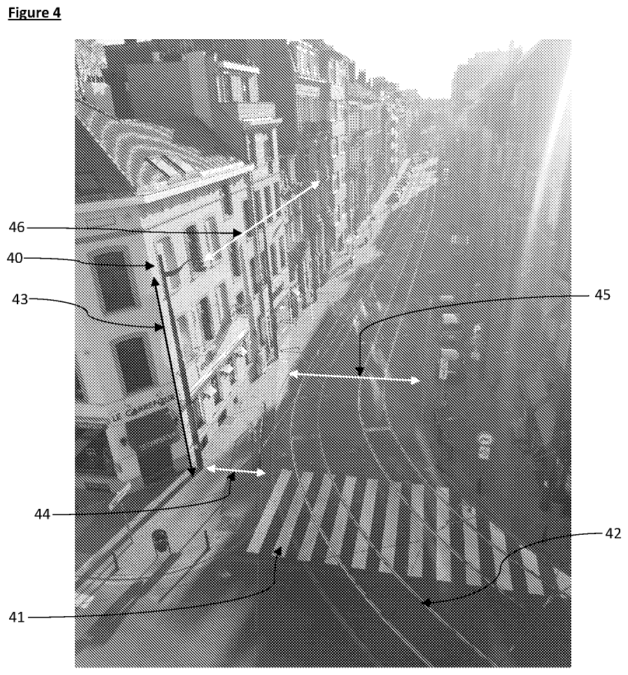

FIG. 4 depicts a visual representation of a lighting site according to exemplary embodiments of the invention. FIG. 4 is a photo of a lighting site to be retrofitted. In other words, only parts of a luminaire needs to be installed. For example, a base support of the at least one luminaire may stay when doing the installation.

In the embodiment of FIG. 4, the lighting site represented is neighboring a pedestrian crossing located at the cross-road of two city streets. A luminaire 40 to be retrofitted is installed at a corner of the cross-road. The luminaire 40 is pole-mounted. A first luminaire installation characteristic of the lighting site may be obtained by obtaining the at least one visual representation of the first lighting site depicted in FIG. 4 and extracting, from the at least one visual representation, the first luminaire installation characteristic. More than one luminaire installation characteristic may be extracted from the at least one visual representation. Additionally, the at least one visual representation may be completed by other visual representations.

The luminaire 40 is neighboring a pedestrian crossing 41, and rails 42 of a passing tramway. Two sets of rails 42 are present in FIG. 4 and it can be deducted that the traffic goes in both directions. Additionally, vehicles such as cars can also circulate on the two sets of rails 42. With reference to FIG. 2, various information corresponding to luminaire installation characteristics may be extracted from FIG. 4. The extracted luminaire installation characteristics may be at least: a luminaire height 43, a luminaire overhang 44, a width of the street 45, a number of lanes, a traffic direction, a type of pathway user, a spacing 46 between the pole-mounted luminaire 40 and the neighboring wall-mounted luminaire, a proximity to a neighboring building, characteristics of the neighboring buildings, etc.

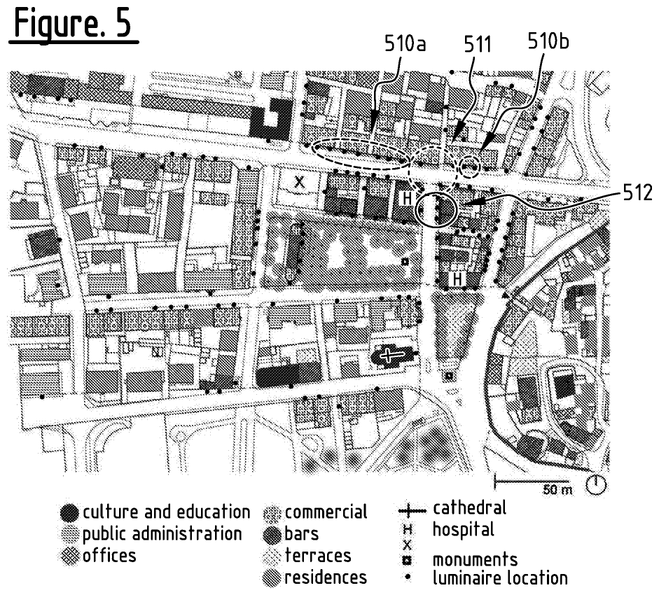

FIG. 5 depicts a visual representation of a plurality of lighting sites according to exemplary embodiments of the invention. FIG. 5 is an architectural map of the plurality of lighting sites 510a, 510b, 511, 512 where luminaires needs to be installed. Positions of base supports of the luminaires may be known and marked on the architectural map.

In the embodiment of FIG. 5, there may be three lighting sites 510a, 510b, 511, 512 spread across several streets of a city neighborhood and the plurality of lighting sites 510a, 510b, 511, 512 can be better visualized using an architectural map with a top view of the city neighborhood.

The locations of the luminaires to be installed or retrofitted may be identified with black dots. The first lighting site 510a, 510b may be neighboring a standard street and spread in two street sections, i.e. two locations along the street: a first location 510a with seven luminaires to be installed, and a second location 510b with two luminaires to be installed. The second lighting site 511 may correspond to a street crossing with four luminaires to be installed, one at each corner of the crossroad. The third lighting site 512 may correspond to an area neighboring an entrance of a hospital with four luminaires to be installed.

The selected list of the at least one suitable luminaire design may comprise a plurality of luminaire designs, each of the plurality of luminaire designs corresponding to a luminaire design suitable for the first, second, or third lighting site 510a, 510b, 511, 512 in order to have the corresponding luminaire design adapted to the function and/or lighting regulations of each lighting site 510a, 510b, 511, 512. For example, a first luminaire design in the list of the at least one suitable luminaire design may correspond to a luminaire design suitable for the first lighting site 510a, 510b, a second luminaire design suitable for the second lighting site 511, and a third luminaire design suitable for the third lighting site 512. In another embodiment the selected list may comprise first and second luminaire designs both suitable for the first lighting sites 510a, 510b, and a second luminaire design suitable for the second lighting site 511, and three different luminaire designs suitable for the third lighting site 512.

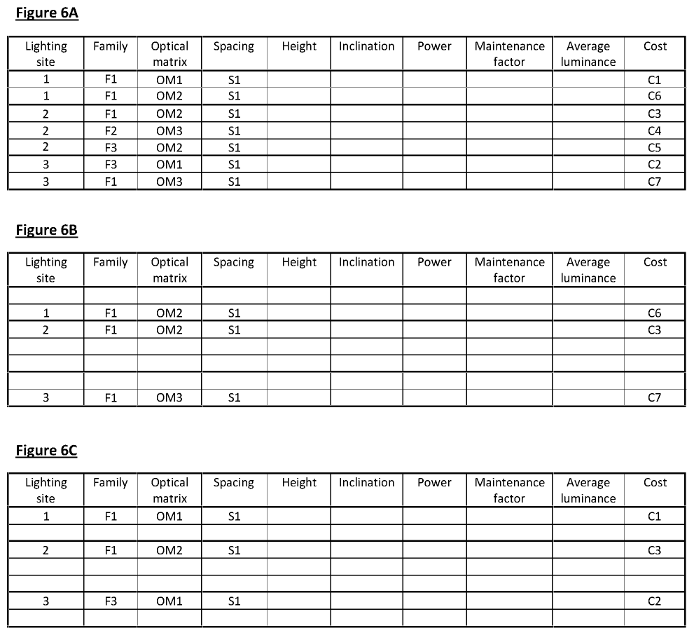

FIGS. 6A-6C illustrate schematically a view of a selected list, and two views of a sorted list, respectively, according to exemplary embodiments of the present invention. It is to be noted that FIGS. 6A-6C illustrate simplified views of embodiments of the invention for understanding purposes, as the number of parameters to consider and the number of luminaire designs, in the selected list for example, can usually be large depending on the luminaire design database.

In the embodiment of FIGS. 6A-6C, there may be three lighting sites named 1, 2, 3 with luminaires to be installed. After obtaining luminaire installation characteristics for the three lighting sites, there may be a step of selecting, based on the first luminaire installation characteristic, on the second luminaire installation characteristic, on the third luminaire installation characteristic, and on a database with a plurality of luminaire designs, a list comprising for each lighting site at least one suitable luminaire design with at least one suitable configuration parameter of said plurality of luminaire designs.

In the embodiment of FIG. 6A, each of the luminaire design selected may be seen as a row of a table. For the first lighting site 1, there may be two suitable luminaire designs selected; for the second lighting site 2, there may be three suitable luminaire designs selected; for the third lighting site 3, there may be two suitable luminaire designs selected.

In the embodiment of FIGS. 6A-6C, the luminaire design may be characterized by a plurality of configuration parameters and a plurality of other parameters, commercial-related for example. Each luminaire design of FIGS. 6A-6C may be characterized by a luminaire family, an optical matrix of a luminaire head, an installation spacing of a base support, an installation height of the luminaire head, an installation inclination of the luminaire head, a power of the luminaire, a maintenance factor of the luminaire, an average illuminance of the luminaire head, a purchase cost of the luminaire. For the three lighting sites, the installation spacing of the base support may be the same and fixed.

In the embodiment of FIG. 6B, two preferential parameters have been selected in order of importance: the luminaire family as a first preferential parameter, and the optical matrix as the second preferential parameter. As a result, when sorting the selected list, luminaire designs for each lighting site sharing a common luminaire family may be kept; then if there is more than one luminaire design for a given lighting site in the list, common optical matrices will be the criteria of choice. Applying the first preferential parameter and the second preferential parameter in sequence may result in the sorted list of the embodiment of FIG. 6B.

Alternatively, in the embodiment of FIG. 6C, a user may prioritize cost over logistics improvement. By selecting purchase cost as the preferential parameter, one may obtain the sorted list of FIG. 6C with only the lowest priced luminaire design for each lighting site, said costs ranging from the lowest (C1) to the highest (C7).

In an embodiment, the sorting of the list may be modulated so that there is a minimum number of luminaire designs left per lighting site, if possible, after the sorting.

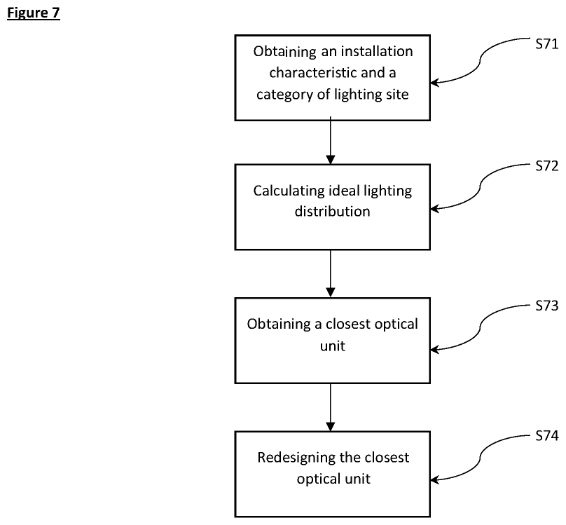

FIG. 7 illustrates a flow chart of an optical unit designing method according to exemplary embodiments of the present invention. By optical unit, it is meant one or more optical elements shaping the light emitted from the light source unit, e.g. the optical unit may comprise any one or more of the following optical elements: a lens element, reflector, backlight, filter, collimator, anti-glare frame. In an embodiment, the optical unit may be a single optical plate with an array of optical elements of only one kind, or with a plurality of rows or columns with a first kind of optical elements and another plurality of rows or columns with a second kind of optical elements. In another embodiment, the optical unit may comprise two or more optical plates of a similar or different kind.

As can be seen in the embodiment of FIG. 7, the method comprises the step S71 of obtaining at least one luminaire installation characteristic associated to a lighting site and a category of the lighting site. The lighting site may be defined following different categories, each category corresponding to a different illumination scheme and/or type of the pathway within and/or neighboring the related lighting site. The lighting site may be any one of: a standard motorway section, a pedestrian crossing, a pedestrian zone, a square, a bicycle lane, a standard road section, a road crossing, a conflict zone, a marketplace, a bridge, an industry hall, an airport, a stadium, a warehouse, etc. Generally, types of pathways are defined according to the lighting regulations, or standards, of the geographical area where the lighting site is located, such as EN13201, IES RP-8, CIE 115.

The category of the lighting site and the at least one luminaire installation characteristic may be obtained in a similar manner as described with respect to step S10 in the embodiment of FIG. 1.

In the embodiment of FIG. 7, the method comprises the step S72 of calculating a theoretical desired lighting distribution based on the category of the lighting site and on the at least one luminaire installation characteristic. By desired lighting distribution, it is meant a lighting distribution offering the optimal lighting conditions in terms of uniformity of the lighting and intensity of the lighting to users of the lighting site. Calculation of the theoretical desired lighting distribution is generally known by the skilled person.

In the embodiment of FIG. 7, the method comprises the step S73 of obtaining a closest optical unit comprising a plurality of optical elements, preferably lens elements, based on the desired lighting distribution and based on a database with a plurality of different optical elements, wherein the plurality of different optical elements comprises preferably a plurality of different lens elements. In an embodiment, the database with the plurality of different optical elements may be stored on a server of a luminaire manufacturer. The plurality of similar optical elements may be a plurality of similar lens elements, preferably organized in an array with a plurality of rows and a plurality of columns. A practical lighting distribution may be calculated for each different optical element in the database with the plurality of different optical elements. Each of the practical lighting distributions may be compared with the desired lighting distribution in order to find a closest practical lighting distribution whose difference with the desired lighting distribution is the smallest among the plurality of practical lighting distributions. The closest optical unit may be obtained by using optical elements associated with the closest lighting distribution.

In the embodiment of FIG. 7, the method comprises the step S74 of re-designing the closest optical unit based on the desired lighting distribution, on the closest optical unit, and on the database with the plurality of different optical elements. By re-designing, it is meant modifying by altering and/or adding optical elements of the closest optical unit such that the re-designed closest optical unit may have a lighting distribution closer to the desired lighting distribution. In re-designing, one can limit an amount of modifications to the closest optical unit. For example, one can fix a maximum number of additional optical elements to add to the closest optical unit. In another embodiment, the closest optical unit may be altered by using different kinds of optical elements instead of optical elements of one kind, and a number of optical element kinds may be limited. An optical unit comprising a plurality of optical plates of the same kind may thus be re-designed as a composition of optical plates of different kinds, or a new optical plate may be created comprising a plurality of optical elements of different kinds.

The optical unit may be defined as an ensemble of optical elements shaping the light emitted from the light source unit, e.g. lens elements, reflectors, backlights, filters, collimators, anti-glare frames. The skilled person will understand that a plurality of optical elements may be combined freely as part of one or more optical plates, and that the one or more optical plates may also be disposed freely one with respect to the other in order to obtained a desired light distribution by the association of the light source unit and the optical unit.

In another embodiment, the above described method in the embodiment of FIG. 7 may be applied based on a first luminaire installation characteristic of a first lighting site and on a category of the first lighting site, and based on a second luminaire installation characteristic of a second lighting site and on a category of the second lighting site. In implementing the method, one can obtain a list comprising, for each lighting site, at least one re-designed optical unit, wherein the at least one re-designed optical unit may be the same or different for the first lighting site and the second lighting site. By taking into account the first lighting site and the second lighting site, one can sort the list based on a number of common optical elements between the at least one re-designed optical unit for the first lighting site and the at least one re-designed optical unit for the second lighting site. Optionally, the sorting may also be based on a weight of the first lighting site and of the second lighting site.

Whilst the principles of the invention have been set out above in connection with specific embodiments, it is to be understood that this description is merely made by way of example and not as a limitation of the scope of protection which is determined by the appended claims.

1. A method for selecting and sorting at least one luminaire design, said method comprising the following steps:
obtaining a first luminaire installation characteristic associated to a first lighting site;
obtaining a second luminaire installation characteristic associated to a second lighting site,
wherein each of the first lighting site and the second lighting site corresponds to a location for installing at least one luminaire neighboring a pathway;
optionally, associating a first weight to the first lighting site and a second weight to the second lighting site, said first weight and second weight being related to a comparison between the first lighting site and the second lighting site;
selecting, based on the first luminaire installation characteristic, on the second luminaire installation characteristic, on a database with a plurality of luminaire designs, and, optionally, based on parameters of a lighting regulation, and/or, optionally, based on the first weight of the first lighting site and on the second weight of the second lighting site, a list comprising, for each lighting site, at least one suitable luminaire design with at least one suitable configuration parameter of said plurality of luminaire designs, wherein a luminaire design may be the same or different for the first lighting site and the second lighting site; and
sorting the list based on at least one preferential parameter, preferably related to a compatibility level with the first lighting site and the second lighting site, and, optionally, based on the first weight of the first lighting site and on the second weight of the second lighting site.

2. The method according to claim 1, wherein each of the first luminaire installation characteristic and the second luminaire installation characteristic comprises: a pathway width, an interval distance between two neighboring luminaire base supports, a pathway surface material, pathway surface optical properties, a height of a luminaire head of the at least one luminaire, a number of lanes of the pathway, one or more circulation directions of the pathway, a lateral distance between the pathway and the at least one luminaire base support, a lateral dimension of a hard shoulder of the pathway, an arrangement pattern of a group of luminaires including the at least one luminaire along the pathway, a bracket length of the luminaire head of the at least one luminaire, an inclination of the luminaire head of the at least one luminaire, a presence of a base support for a luminaire, a location of the base support respective to the one or more circulation directions, a proximity with a neighboring building, characteristics of the neighboring building, a number of luminaire heads per base support, a presence of a conflict zone in the lighting site, or a type of the pathway.

3. The method according to claim 1, wherein the sorted list includes a first luminaire design suitable for the first lighting site, and a second luminaire design suitable for the second lighting site, said first luminaire design and second luminaire design having at least one similar or identical configuration parameter,
optionally wherein the at least one similar or identical configuration parameter comprises: a luminaire family, a luminaire head housing, a light source unit, an optical unit, or a luminaire driver, and/or
wherein the first lighting site and/or the second lighting site comprises at least five luminaires to be installed, preferably at least ten luminaires to be installed, and/or
wherein the preferential parameter is related to: a compatibility level with a lighting site, a luminaire family, an installation budget, a compliancy with a lighting regulation, a power consumption per kilometer, a number of luminaires to be installed, a maximum wattage of the at least one luminaire to be installed, an aesthetical consideration, a type of light source, a glaring index, a luminaire managing option, a number of parts of a luminaire design, a lighting uniformity, a lighting intensity, an average illuminance, a total cost of ownership, a lifetime, a method of installation, an operating temperature, a recycling factor, a certificate, a commercial brand, an electrical connection type, or a secondary functionality of the luminaire.

4. (canceled)

5. (canceled)

6. (canceled)

7. The method according to claim 1, wherein the method further comprises:
providing an input corresponding to a third luminaire installation characteristic of the first lighting site and/or the second lighting site, and
wherein the selecting of the list of the at least one suitable luminaire design is further based on the third luminaire installation characteristic.

8. The method according to claim 1, wherein the method further comprises:
providing an input corresponding to another preferential parameter relative to the plurality of luminaire designs; and
sorting the list of the at least one suitable luminaire design further based on the another preferential parameter.

9. The method according to claim 1, wherein the method further comprises:
obtaining, from a regulation database, a lighting regulation associated to the first lighting site and/or the second lighting site and/or obtaining, from a stock database, a list of available luminaire parts, and
wherein the selecting of the list of the at least one suitable luminaire design is further based on the obtained lighting regulation and/or on the obtained list of available luminaire parts.

10. (canceled)

11. The method according to claim 1, wherein the selecting of the list of the at least one suitable luminaire design is further based on a further luminaire installation characteristic of a further lighting site, and/or
wherein the first lighting site and/or the second lighting site corresponds to the location for installing, for the at least one luminaire, at least one luminaire head, optionally combined with an associated luminaire head bracket, to at least one existing base support.

12. (canceled)

13. The method according to claim 1, said method further comprising:
obtaining at least one visual representation of the first lighting site and/or the second lighting site and/or a further lighting site; and
extracting, from the at least one visual representation, the first luminaire installation characteristic and/or second luminaire installation characteristic and/or a third luminaire installation characteristic and/or a further luminaire installation characteristic,
wherein the selecting of the list of the at least one suitable luminaire design is further based on the extracted first and/or second and/or third and/or another luminaire installation characteristic.

14. The method according to claim 13, wherein the at least one visual representation is any one, or a combination, of: a photograph, a video, a map, a three-dimensional view, and a street-level visualization, and/or
wherein the at least one visual representation comprises an indication corresponding to a location of at least one luminaire base support within the first lighting site and/or the second lighting site, and/or
wherein the at least one visual representation comprises a first and a second visual representation of the first lighting site and/or the second lighting site and/or the further lighting site, said first visual representation being different from said second visual representation; and the extracting of the first and/or second and/or third and/or further luminaire installation characteristic is based on the first and the second visual representations of the first lighting site and/or the second lighting site and/or the further lighting site, and/or
wherein the method further comprises outputting an altered visual representation of the first lighting site and/or the second lighting site with at least one installed luminaire, based on the list of the at least one suitable luminaire design and on the at least one visual representation of the first lighting site and/or the second lighting site.

15. (canceled)

16. (canceled)

17. (canceled)

18. A computer program comprising instructions which, when the program is executed by a computer, cause the computer to carry out the method according to claim 1.

19. A computer controlled system for selecting and sorting at least one luminaire design, said system including:
a data entry means adapted to receive:
a first luminaire installation characteristic associated to a first lighting site;
a second luminaire installation characteristic associated to a second lighting site,
wherein each of the first lighting site and the second lighting site corresponds to a location for installing at least one luminaire neighboring a pathway;
optionally, a lighting regulation; and
a database comprising a plurality of luminaire designs;
a memory coupled to said data entry means for storing the first luminaire installation characteristic, the second luminaire installation characteristic, and said database comprising the plurality of luminaire designs, and optionally the lighting regulation;
a processor coupled to said memory; and
a display coupled to said processor,
wherein the processor is further configured for:
obtaining, from the memory, the first luminaire installation characteristic;
obtaining, from the memory the second luminaire installation characteristic;
optionally, associating a first weight to the first lighting site and a second weight to the second lighting site, said first weight and second weight being related to a comparison between the first lighting site and the second lighting site;
optionally, obtaining, from the memory, parameters of the lighting regulation;
selecting, based on the first luminaire installation characteristic, on the second luminaire installation characteristic, on the database with a plurality of luminaire designs, and, optionally, based on parameters of the lighting regulation, and/or, optionally, based on the first weight of the first lighting site and on the second weight of the second lighting site, a list comprising for each lighting site at least one suitable luminaire design with at least one suitable configuration parameter of said plurality of luminaire designs, wherein a luminaire design may be the same or different for the first lighting site and the second lighting site;
outputting the selected list of the at least one suitable luminaire design via the display;
sorting the list based on a preferential parameter, preferably related to a compatibility level with the first lighting site and the second lighting site, and, optionally, based on the first weight of the first lighting site and on the second weight of the second lighting site; and
outputting the sorted list of the at least one suitable luminaire design via the display.

20. The system according to claim 19, wherein the first luminaire installation characteristic and the second luminaire installation characteristic are each: a pathway width, an interval distance between two neighboring luminaire base supports, a pathway surface material, pathway surface optical properties, a height of a luminaire head of the at least one luminaire, a number of lanes of the pathway, one or more circulation directions of the pathway, a lateral distance between the pathway and the at least one luminaire base support, a lateral dimension of a hard shoulder of the pathway, an arrangement pattern of a group of luminaires including the at least one luminaire, a bracket length of the luminaire head of the at least one luminaire, an inclination of the luminaire head of the at least one luminaire, a presence of a base support for a luminaire, a location of the base support respective to the one or more circulation directions, a proximity with a neighboring building, characteristics of the neighboring building, a number of luminaire heads per base support, a presence of a conflict zone in the lighting site, or a type of pathway.

21. The system according to claim 19 or 20, wherein the sorted list includes a first luminaire design suitable for the first lighting site, and a second luminaire design suitable for the second lighting site, said first luminaire design and second luminaire design having at least one similar or identical configuration parameter,
optionally wherein the at least one similar or identical configuration parameter comprises: a luminaire family, a luminaire head housing, a light source unit, an optical unit, or a luminaire driver, and/or
wherein the first lighting site and/or the second lighting site comprises at least five luminaires to be installed, preferably at least ten luminaires to be installed, and/or
wherein the preferential parameter is related to: the compatibility level with the first lighting site and the second lighting site, a luminaire family, an installation budget, a compliancy with a lighting regulation, a power consumption per kilometer, a number of luminaires to be installed, a maximum wattage of the at least one luminaire to be installed, an aesthetical consideration, a type of light source, a glaring index, a luminaire managing option, a number of parts of a luminaire design, a lighting uniformity, a lighting intensity, an average illuminance, a total cost of ownership, a lifetime, a method of installation, an operating temperature, a recycling factor, a certificate, a commercial brand, an electrical connection type, or a secondary functionality of the luminaire.

22. (canceled)

23. (canceled)

24. (canceled)

25. The system according to claim 19, wherein the processor is further configured for:
providing an input interface for inputting a third luminaire installation characteristic of the first lighting site and/or the second lighting site, and
wherein the selecting of the list of the at least one suitable luminaire design is further based on the third luminaire installation characteristic.

26. The system according to claim 19, wherein the processor is further configured for:
providing an input interface for inputting another preferential parameter relative to the plurality of luminaire designs; and
sorting the list of the at least one suitable luminaire design further based on the another preferential parameter.

27. The system according to claim 19, wherein the processor is further configured for:
obtaining, from a regulation database, a lighting regulation associated to the first lighting site and/or the second lighting site and/or obtaining, from a stock database, a list of available luminaire parts, and
wherein the selecting of the list of the at least one suitable luminaire design is further based on the obtained lighting regulation and/or on the obtained list of available luminaire parts.

28. (canceled)

29. The system according to claim 19, wherein the selecting of the list of the at least one suitable luminaire design is further based on a further luminaire installation characteristic of a further lighting site, and/or
wherein the first lighting site and/or the second lighting site corresponds to the location for installing, for the at least one luminaire, at least one luminaire head, optionally combined with an associated luminaire head bracket, to at least one existing base support.

30. (canceled)

31. The system according to claim 19, wherein the data entry means is further adapted to receive at least one visual representation of the first lighting site and/or the second lighting site and/or a further lighting site,
wherein the memory coupled to said data entry means is configured for storing the at least one visual representation,
wherein the processor is further configured for:
obtaining, from the memory, the at least one visual representation of the first lighting site and/or the second lighting site and/or the further lighting site; and
extracting, from the at least one visual representation, the first luminaire installation characteristic and/or second luminaire installation characteristic and/or a third luminaire installation characteristic and/or a further luminaire installation characteristic, and
wherein the selecting of the list of the at least one suitable luminaire design is further based on the extracted first and/or second and/or third and/or further installation characteristic.

32. The system according to claim 31, wherein the at least one visual representation is any one, or a combination, of: a photograph, a video, a map, a three-dimensional view, and a street-level visualization, and/or
wherein the at least one visual representation comprises an indication corresponding to a location of at least one luminaire base support within the first lighting site and/or the second lighting site, and/or
wherein the at least one visual representation comprises a first and a second visual representation of the first lighting site and/or the second lighting site and/or the further lighting site, said first visual representation being different from said second visual representation, and
wherein the extracting of the first and/or second and/or third and/or further luminaire installation characteristic is based on the first and the second visual representations of the first lighting site and/or the second lighting site and/or the further lighting site, and/or
wherein the processor is further configured for outputting an altered visual representation of the first lighting site and/or the second lighting site with at least one installed luminaire, based on the list of the at least one suitable luminaire design and on the at least one visual representation of the first lighting site and/or the second lighting site.

33. (canceled)

34. (canceled)

35. (canceled)

36. The method according to claim 1, wherein the step of selecting is performed after the steps of obtaining, and wherein the step of sorting is performed after the step of selecting.
